(19) United States
(12) Patent Application Publication
(10) Pub. No.: US 2026/0256035 A1
(43) Pub. Date: Aug. 27, 2026

(54) SEMICONDUCTOR DEVICE

(71) Applicant: ROHM Co., LTD., Kyoto (JP)

(72) Inventors: Junsuke Satake, Kyoto (JP); Taro Nishioka, Kyoto (JP)

(21) Appl. No.: 19/550,805

(22) Filed: Feb. 26, 2026

(30) Foreign Application Priority Data
Feb. 27, 2025 (JP) 2025-030126

(51) Int. Cl. H10W 90/00; H10W 70/40; H10W 74/00

(52) U.S. Cl. CPC H10W 90/811; H10W 70/421; H10W 74/00; H10W 90/756

(57) ABSTRACT

Provided is a semiconductor device including a first lead, a second lead separated from the first lead in a first direction, at least one first semiconductor element loaded on the first lead, a plurality of second semiconductor elements loaded on the second lead, a third semiconductor element loaded on the first lead or the second lead, and, a sealing resin that covers the first lead, the second lead, the at least one first semiconductor element, the plurality of second semiconductor elements, and the third semiconductor element, in which the third semiconductor element is interposed between the at least one first semiconductor element and the plurality of second semiconductor elements such that the at least one first semiconductor element and the plurality of second semiconductor elements have different potentials, and the plurality of second semiconductor elements is aligned along a second direction orthogonal to the first direction.

The present disclosure contains subject matter related to that disclosed in Japanese Priority Patent Application JP 2025-030126 filed in the Japan Patent Office on Feb. 27, 2025, the entire content of which is hereby incorporated by reference.

### BACKGROUND

The present disclosure relates to a semiconductor device.

An inverter device in the related art is provided with a switching element such as an insulated gate bipolar transistor (IGBT) or a metal oxide semiconductor field effect transistor (MOSFET), a control element, and a driving element. In the inverter device in the related art, a power supply voltage supplied to the control element is low (approximately 5 V), whereas a power supply voltage supplied to the driving element is high (approximately 600 V or more) in some cases. An insulating element is used in some cases as a unit for transmitting a signal between a plurality of elements having different power supply voltages as described above. For example, Japanese Patent Laid-open No. 2009-49035 discloses an example of a semiconductor device (intelligent power module) provided with an insulating element. In the case where a plurality of circuits are formed in one element as in the semiconductor device disclosed in Japanese Patent Laid-open No. 2009-49035, there is a risk that a plurality of circuits cause unintended mutual interference. Such interference may cause the semiconductor device to fail and reduce the reliability of the semiconductor device.

### BRIEF DESCRIPTION OF THE DRAWINGS

FIG. 1 is a plan view depicting a semiconductor device according to a first embodiment;

FIG. 2 is a diagram in which a sealing resin is depicted by an imaginary line in the plan view of FIG. 1;

FIG. 3 is a front view depicting the semiconductor device according to the first embodiment;

FIG. 4 is a left side view depicting the semiconductor device according to the first embodiment;

FIG. 5 is a right side view depicting the semiconductor device according to the first embodiment;

FIG. 6 is a cross-sectional view taken along line VI-VI of FIG. 2;

FIG. 7 is a cross-sectional view taken along line VII-VII of FIG. 2;

FIG. 8 is a partially-enlarged cross-sectional view of FIG. 7;

FIG. 9 is a cross-sectional view depicting an internal structure of one (insulating element) of a plurality of semiconductor elements of the semiconductor device according to the first embodiment;

FIG. 10 is a plan view depicting one step of a manufacturing method of the semiconductor device according to the first embodiment;

FIG. 11 is a plan view depicting one step of the manufacturing method of the semiconductor device according to the first embodiment;

FIG. 12 is a plan view depicting one step of the manufacturing method of the semiconductor device according to the first embodiment;

FIG. 13 is a plan view depicting one step of the manufacturing method of the semiconductor device according to the first embodiment;

FIG. 14 is a plan view depicting one step of the manufacturing method of the semiconductor device according to the first embodiment;

FIG. 15 is a plan view depicting one step of the manufacturing method of the semiconductor device according to the first embodiment;

FIG. 16 is an electrical schematic diagram depicting the semiconductor device according to the first embodiment;

FIG. 17 is a plan view depicting a semiconductor device according to a first modified example of the first embodiment, in which a sealing resin is depicted by an imaginary line;

FIG. 18 is a cross-sectional view taken along line XVIII-XVIII of FIG. 17;

FIG. 19 is a plan view depicting a semiconductor device according to a second embodiment, in which a sealing resin is depicted by an imaginary line;

FIG. 20 is an enlarged view of a region XX of FIG. 19;

FIG. 21 is a cross-sectional view along line XXI-XXI of FIG. 19;

FIG. 22 is a plan view depicting a semiconductor device according to a first modified example of the second embodiment, in which a sealing resin is depicted by an imaginary line;

FIG. 23 is a cross-sectional view taken along line XXIII-XXIII of FIG. 22;

FIG. 24 is a plan view depicting a semiconductor device according to a third embodiment, in which a sealing resin is depicted by an imaginary line;

FIG. 25 is an enlarged view of a region XXV of FIG. 24;

FIG. 26 is a cross-sectional view taken along line XXVI-XXVI of FIG. 24;

FIG. 27 is an electrical schematic diagram depicting the semiconductor device according to the third embodiment;

FIG. 28 is a plan view depicting a semiconductor device according to a fourth embodiment, in which a sealing resin is depicted by an imaginary line;

FIG. 29 is a cross-sectional view taken along line XXIX-XXIX of FIG. 28; and

FIG. 30 is an electrical schematic diagram depicting the semiconductor device according to the fourth embodiment.

### DETAILED DESCRIPTION

Preferred embodiments of a semiconductor device of the present disclosure and a manufacturing method thereof will be described below with reference to the drawings. The constitutional elements illustrated in the drawings are examples for explaining the semiconductor device of the present disclosure. The disclosure according to the claims does not require all of the constitutional elements depicted in the drawings and the specification.

### First Embodiment

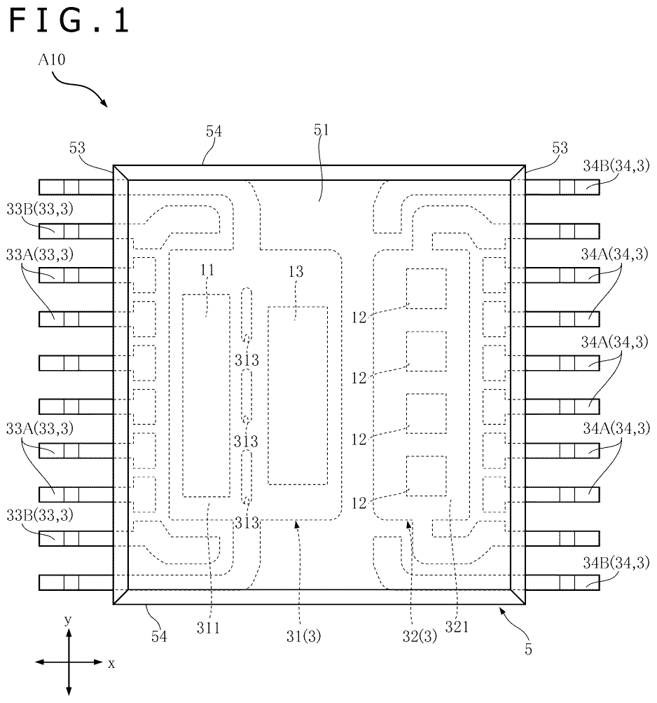

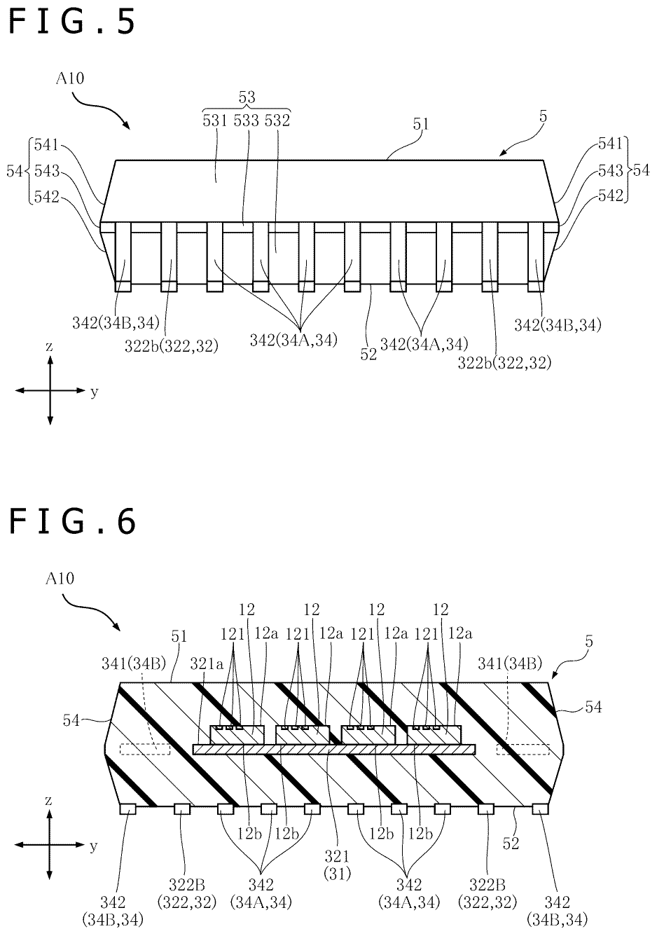

FIGS. 1 through 9 depict a semiconductor device A10 according to a first embodiment. As depicted in these drawings, the semiconductor device A10 includes a plurality of semiconductor elements 11, 12, and 13, a conductive support 3, a plurality of connecting members 4, and a sealing resin 5.

The present disclosure will be described with reference to a first direction x, a second direction y, and a third direction z that are orthogonal to one another. The third direction z corresponds, for example, to a third direction of the conductive support 3. In the following description, “in plan view” refers to viewing in the third direction z. One side of the third direction z will be referred to as upward while the other side thereof will be referred to as downward in some cases. It should be noted that the terms “upper,” “lower,” “upward,” “downward,” “upper surface,” and “lower surface” indicate the relative positional relation between the respective components in the third direction z, and are not necessarily terms defining the relation with the gravity direction.

The semiconductor device A10 may be surface-mounted on a wiring substrate of an inverter device of an electric vehicle and a hybrid vehicle, for example. The inverter device generates three-phase alternating current (AC) power for driving a motor from direct current (DC) power of an on-vehicle battery. The semiconductor device A10 is configured to control a switching operation of a switching element such as IGBT or MOSFET. More specifically, the semiconductor device A10 may include a control element (controller) to which a control signal from an engine control unit (ECU) is input, a driving element (gate driver) that converts the control signal into a pulse width modulation (PWM) signal and transmits the PWM signal to targets (for example, six switching elements), and an intermediary element that transmits a signal among a plurality of elements having different power supply voltages. As can be understood from FIGS. 1 and 3 through 5, the package format of the semiconductor device A10 is a small outline package (SOP). The package format of the semiconductor device A10 is not limited to the SOP.

The plurality of semiconductor elements 11, 12, and 13 may be a functional center of the semiconductor device A10. In the present embodiment, the plurality of semiconductor elements 11, 12, and 13 include the semiconductor element 11, a plurality of semiconductor elements 12, and the semiconductor element 13. The semiconductor element 11 is an example of a control element. The plurality of semiconductor elements 12 are an example of a driving element. The semiconductor element 13 is an example of an intermediary element. In the first direction x, the semiconductor element 13 is positioned between the semiconductor element 11 and the plurality of semiconductor elements 12. Accordingly, the semiconductor element 13 is electrically interposed such that the semiconductor element 11 has a potential different from that of the plurality of semiconductor elements 12. In plan view, each of the plurality of semiconductor elements 11, 12, and 13 has a rectangular shape having a long side in the second direction y. It should be noted that the shapes of the plurality of semiconductor elements 11, 12, and 13 in plan view are not limited to the illustrated examples.

The semiconductor element 11 may include a circuit for converting a control signal input from an ECU or other members to a PWM signal, a transmission circuit for transmitting the signal to the semiconductor element 13, and a reception circuit for receiving an electrical signal from the semiconductor element 13.

The semiconductor element 11 may have a main surface 11a and a back surface 11b. The main surface 11a and the back surface 11b are separated from each other in the third direction z. The main surface 11a is the upper surface of the semiconductor element 11, and the back surface 11b is the lower surface of the semiconductor element 11. The back surface 11b faces a lead 31. The main surface 11a may be provided with a plurality of pads 111. Each of compositions of the plurality of pads 111 contains, for example, aluminum (Al).

Each of the plurality of semiconductor elements 12 may include a reception circuit for receiving a PWM signal, a circuit for driving a switching element, based on the signal, and a transmission circuit for transmitting an electrical signal to the semiconductor element 11. The electrical signal is, for example, an output signal from a temperature sensor arranged near a motor. The number of the plurality of semiconductor elements 12 is not limited to any specific number, but is four in the illustrated example.

Each semiconductor element 12 may have a main surface 12a and a back surface 12b. The main surface 12a and the back surface 12b are separated from each other in the third direction z. The main surface 12a is the upper surface of the semiconductor element 12, and the back surface 12b is the lower surface of the semiconductor element 12. The back surface 12b faces a lead 32. The main surface 12a may be provided with a plurality of pads 121. Each of compositions of the plurality of pads 121 contains, for example, Al.

Each semiconductor element 12 includes a first side 12a1, a second side 12a2, a third side 12a3, and a fourth side 12a4 in plan view. The first side 12a1, the second side 12a2, the third side 12a3, and the fourth side 12a4 correspond to the ends of each main surface 12a in the first direction x and the second direction y. The first side 12a1 and the second side 12a2 are separated from each other in the second direction y. The third side 12a3 and the fourth side 12a4 are separated from each other in the first direction x. The main surface 12a is not limited to having the shape illustrated in the example, and may not include at least any one of the first side 12a1, the second side 12a2, the third side 12a3, and the fourth side 12a4.

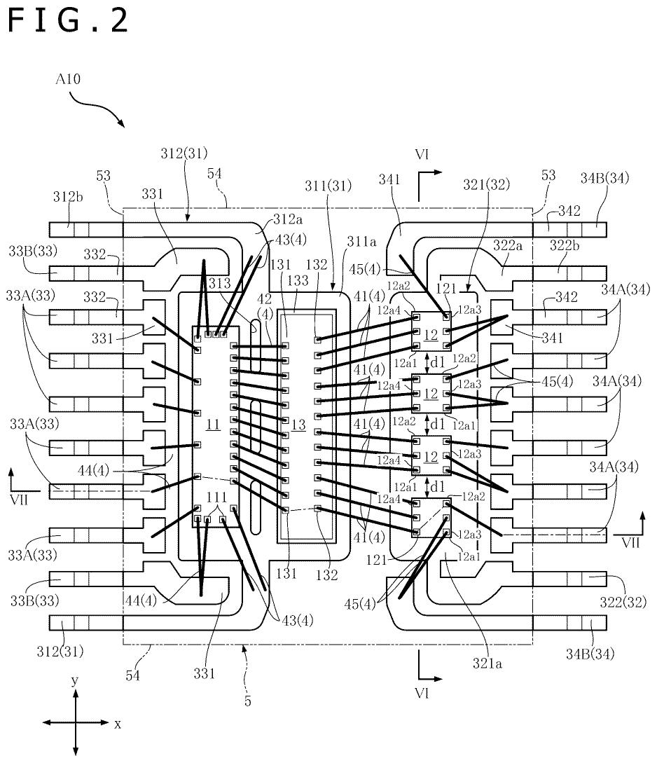

The plurality of semiconductor elements 12 are aligned along the second direction y. The plurality of semiconductor elements 12 are arranged at intervals d1 therebetween in the second direction y. In FIG. 2, the intervals d1 are illustrated. The first side 12a1 faces the second side 12a2 of the semiconductor element 12 that is positioned next thereto in the second direction y. The interval d1 corresponds to the distance between the first side 12a1 and the second side 12a2 of two adjacent semiconductor elements 12. The interval d1 is, for example, equal to or larger than 150μm but equal to or smaller than 1500μm. The plurality of semiconductor elements 12 overlap when viewed in the second direction y. In the example depicted in FIG. 2, the plurality of semiconductor elements 12 are at the same position in the first direction x. Alternatively, the plurality of semiconductor elements 12 may be at different positions in the first direction x.

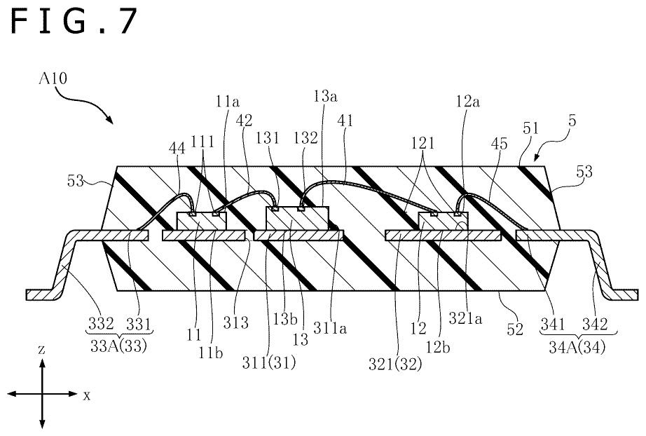

FIG. 6 illustrates an example of cross sections of the plurality of semiconductor elements 12. As depicted in the drawing, the plurality of semiconductor elements 12 have the main surfaces 12a at the same position in the third direction z. That is, the plurality of semiconductor elements 12 have the same thickness. Alternatively, the plurality of semiconductor elements 12 may have the main surfaces 12a at different positions in the third direction z and different thicknesses.

In a motor driver circuit in an inverter device, a half bridge circuit including a low-side (low potential side) switching element and a high-side (high potential side) switching element is typically configured. An example in which these switching elements are MOSFETs will be described below. In the low-side switching element, both the reference potential of the source of the element and the reference potential of the gate driver for driving the element are ground. Meanwhile, in the high-side switching element, both the reference potential of the source of the element and the reference potential of the gate driver for driving the element correspond to the potential at an output node of the half-bridge circuit. Since the potential at the output node changes according to the driving of the high-side switching element and the low-side switching element, the reference potential of the gate driver for driving the high-side switching element changes. In the case where the high-side switching element is on, the reference potential is equivalent (for example, 600 V or more) to a voltage applied to the drain of the high-side switching element. In the semiconductor device A10, the ground of the semiconductor element 11 and the grounds of the plurality of semiconductor elements 12 are separated from each other. Hence, in the case where the semiconductor device A10 is used as the gate driver for driving the high-side switching element, a voltage equivalent to the voltage applied to the drain of the high-side switching element is transiently applied to the grounds of the plurality of semiconductor elements 12.

The semiconductor element 13 may include an insulation type transformer for transmitting a signal between a control circuit and an arm circuit in an insulated state. The insulation transformer is an example of an inductive type semiconductor element 13. Alternatively, the semiconductor element 13 may be of a capacitive type. One example of the capacitive type semiconductor element 13 is a capacitor. Alternatively, the semiconductor element 13 may be a photocoupler.

The semiconductor element 13 may have a main surface 13a and a back surface 13b. The main surface 13a and the back surface 13b are separated from each other in the third direction z. The main surface 13a is the upper surface of the semiconductor element 13, and the back surface 13b is the lower surface of the semiconductor element 13. The back surface 13b faces the lead 31.

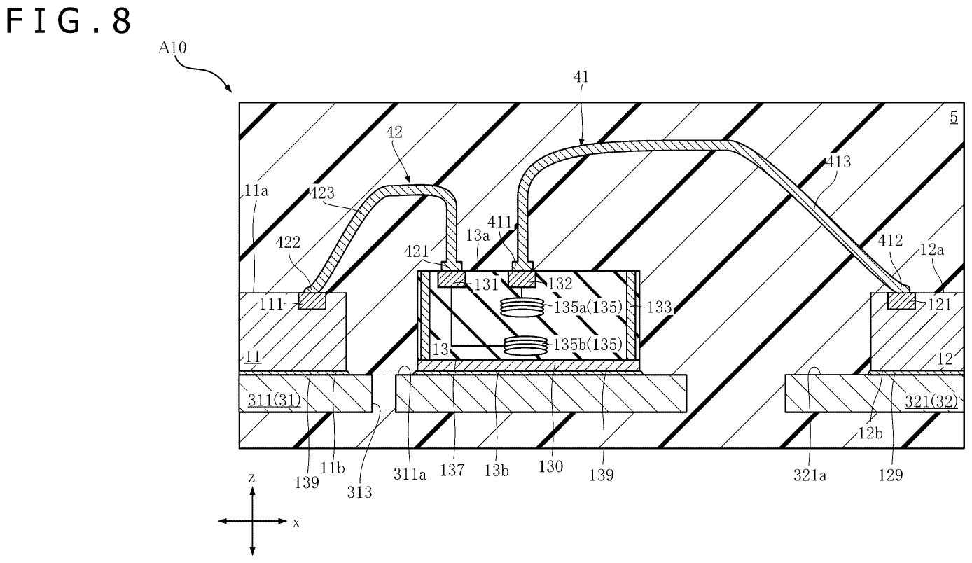

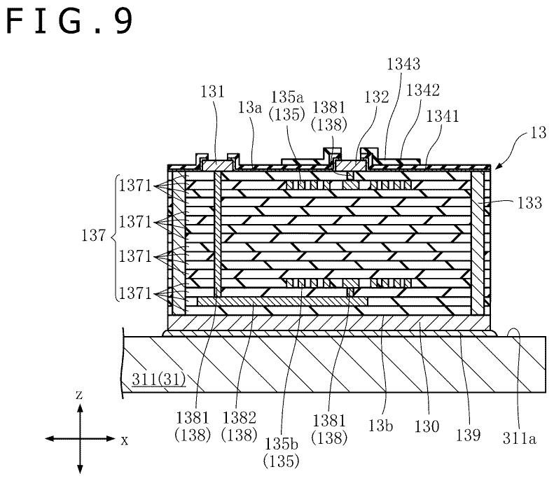

FIGS. 2, 8, and 9 illustrate examples of the configuration of the semiconductor element 13. As depicted in the drawings, the semiconductor element 13 may include a semiconductor substrate 130, a plurality of pads 131, a plurality of pads 132, a seal ring part 133, a protective film 1341, a passivation film 1342, a coil protective film 1343, a functional part 135, a laminated structure 137, and a wiring part 138. The internal structure of the semiconductor element 13 is not limited to the examples illustrated in FIGS. 8 and 9.

A silicon (Si) substrate or a silicon carbide (SiC) substrate, for example, may be applied to the semiconductor substrate 130. An insulating substrate such as a ceramic substrate or a resin substrate may be used for the semiconductor element 13 instead of the semiconductor substrate 130.

The plurality of pads 131 and 132 are provided on the main surface 13a. Each of compositions of the plurality of pads 131 and 132 contains, for example, Al.

The seal ring part 133 is formed along each of four outer circumferential edges of the semiconductor element 13 in plan view and surrounds the outer circumference of the circuit formation region. The seal ring part 133 is erected on the semiconductor substrate 130 and penetrates the laminated structure 137 in the third direction z. The potential of the seal ring part 133 may be the same as the potential of the semiconductor substrate 130. Compositions of the seal ring part 133 contain, for example, copper (Cu) and Al.

The protective film 1341 is laminated on the laminated structure 137. The protective film 1341 contains, for example, silicon dioxide (SiO₂) and has a thickness of approximately 150 nm. The passivation film 1342 is laminated on the protective film 1341. The passivation film 1342 contains, for example, silicon nitride (SiN) and has a thickness of approximately 1000 nm. The coil protective film 1343 selectively covers a region immediately above an upper winding 135a on the passivation film 1342. The coil protective film 1343 contains, for example, polyimide and has a thickness of approximately 4000 nm. As can be understood from FIG. 9, pad openings for exposing each pad 131 and each pad 132 are formed in the protective film 1341, the passivation film 1342, and the coil protective film 1343. The respective configuration materials and thicknesses of the protective film 1341, the passivation film 1342, and the coil protective film 1343 are not limited to the examples described above.

The laminated structure 137 is formed on the semiconductor substrate 130. As depicted in FIG. 9, the laminated structure 137 includes a plurality of insulation layers 1371. The plurality of insulation layers 1371 are laminated on the upper surface of the semiconductor substrate 130. Each of the plurality of insulation layers 1371, except the insulation layer 1371 of the lowermost layer in contact with the upper surface of the semiconductor substrate 130, includes a laminated structure of an etching stopper film of a lower layer and an interlayer insulation film of an upper layer. The insulation layer 1371 of the lowermost layer includes only an interlayer insulation layer. As the etching stopper film, for example, a silicon nitride film (SiN film) or a silicon carbide film (SiC film), a silicon nitrocarbide film (SiCN film) can be used, and as the interlayer insulation film, for example, a silicon oxide film (SiO₂ film) can be used. The dimension of the plurality of insulation layers 1371 in the third direction z is not limited to any particular dimension, and is, for example, 2.4 μm. The thickness of each of the plurality of insulation layers 1371 may be appropriately changed. The number of insulation layers 1371 is not limited to the illustrated example, and may be appropriately changed according to, for example, the magnitude of the voltage applied to each pad 131 and each pad 132.

The functional part 135 serves as a functional center of transmitting an electrical signal in an insulated state in the semiconductor element 13. The functional part 135 includes a plurality of upper windings 135a and a plurality of lower windings 135b between the semiconductor substrate 130 and the pad 132 in the third direction z. The plurality of upper windings 135a and the plurality of lower windings 135b are magnetically coupled to each other. Accordingly, each upper winding 135a forms a functional set with one of the plurality of lower windings 135b. That is, the functional part 135 has therein a plurality of sets of the upper windings 135a and the lower windings 135b. Each of the plurality of upper windings 135a and the plurality of lower windings 135b is wound, for example, in a planar shape. Each of the upper windings 135a and the lower windings 135b may sterically wind a plurality of insulation layers 1371. However, in order to reduce the thickness of the semiconductor element 13, it is preferable that each of the upper windings 135a and the lower windings 135b be wound around one insulation layer 1371 in a planar shape.

FIG. 8 illustrates one of the plurality of sets of the upper windings 135a and the lower windings 135b. The plurality of sets of the upper windings 135a and the lower windings 135b may be similarly provided with the features depicted in FIG. 8. The plurality of sets of the upper windings 135a and the lower windings 135b will be described below as an “upper winding 135a” and a “lower winding 135b” in some cases without distinguishing them from each other. The upper winding 135a and the lower winding 135b are separated from and face each other in the third direction z.

The upper winding 135a and the lower winding 135b are provided in different insulation layers 1371 in the laminated structure 137. That is, the upper winding 135a and the lower winding 135b face each other while sandwiching one or more insulation layers 1371. In the illustrated example, the lower winding 135b is formed in the insulation layer 1371 of the fourth layer counted from the semiconductor substrate 130, and the upper winding 135a is formed in the insulation layer 1371 of the 15th layer while sandwiching 10 insulation layers 1371 between the upper winding 135a and the lower winding 135b. As the number of insulation layers 1371 between the upper winding 135a and the lower winding 135b is larger, the dielectric breakdown voltage in the semiconductor element 13 can be made larger, but the thickness (the dimension in the third direction z) of the semiconductor element 13 becomes larger. On the other hand, as the number of insulation layers 1371 between the upper winding 135a and the lower winding 135b is smaller, the dielectric breakdown voltage in the semiconductor element 13 is made smaller, but the thickness (the dimension in the third direction z) of the semiconductor element 13 can be made smaller.

The wiring part 138 electrically connects between each pad 131 and the corresponding lower winding 135b and between each pad 132 and the corresponding upper winding 135a. Each wiring part 138 includes a plurality of through wirings 1381 and drawing wirings 1382. Each of the plurality of through wirings 1381 penetrates one or more insulation layers 1371 in the third direction z. In the example depicted in FIG. 9, the plurality of through wirings 1381 include one connecting the pad 131 and the drawing wiring 1382 to each other, one connecting the drawing wiring 1382 and the lower winding 135b to each other, and one connecting the pad 132 and the upper winding 135a to each other. The drawing wiring 1382 is formed on the insulation layer 1371 of the lowermost layer. The drawing wiring 1382 forms a part of a conductive path between the pad 131 and the lower winding 135b.

The conductive support 3 configures a conductive path between the plurality of semiconductor elements 11, 12, and 13 and the wiring substrate on which the semiconductor device A10 is mounted. The conductive support 3 is obtained from, for example, the same lead frame. As depicted in FIGS. 1, 2, 6, and 7, the conductive support 3 has the lead 31, the lead 32, a plurality of leads 33, and a plurality of leads 34. The shapes and arrangements of the lead 31 and the lead 32 and the shapes, arrangements, and number of leads 33 and leads 34 are not limited to the illustrated examples.

The lead 31 and the lead 32 are separated from each other in the first direction x. In the semiconductor device A10, the semiconductor element 11 and the semiconductor element 13 are loaded on the lead 31, and the plurality of semiconductor elements 12 are loaded on the lead 32.

The lead 31 includes an island part 311. The island part 311 has a loading surface 311a that faces one side (upward) in the third direction z. That is, the loading surface 311a faces the same direction as the main surface 11a. In the present embodiment, the semiconductor element 11 is joined to the loading surface 311a via a conductive joining material 119 and the semiconductor element 13 is joined thereto via a conductive joining material 139. Each of the conductive joining materials 119 and 139 is, for example, solder or metal paste or sintered metal. There is a case where the island part 311 is at the same potential as the semiconductor substrate 130 of the semiconductor element 13. The island part 311 is covered with the sealing resin 5. In the illustrated example, the island part 311 has a rectangular shape in plan view. The thickness of the island part 311 is, for example, equal to or larger than 100 μm but equal to or smaller than 300 μm. Optionally, the island part 311 may be provided with a plurality of through holes 313. Each through hole 313 penetrates the island part 311 in the third direction z. Each through hole 313 has an elliptical shape extending along the second direction y in plan view. Each through hole 313 is positioned between the semiconductor element 11 and the semiconductor element 13.

The potential of the lead 31 is the same as the potential of the semiconductor substrate 130 since the semiconductor element 13 is joined to the lead 31. Further, the lead 31 is electrically connected to the lower winding 135b via the semiconductor element 11. Hence, the potential of the lead 31 is the same as the potential of the lower winding 135b. That is, the potential of the lead 31 is the same as the potential of the semiconductor substrate 130 and the potential of the lower winding 135b.

The lead 31 further includes two terminal parts 312. The two terminal parts 312 extend from both sides of the island part 311 in the second direction y. The two terminal parts 312 are separated from each other in the second direction y. At least one of the two terminal parts 312 is conductive to the ground of the semiconductor element 11.

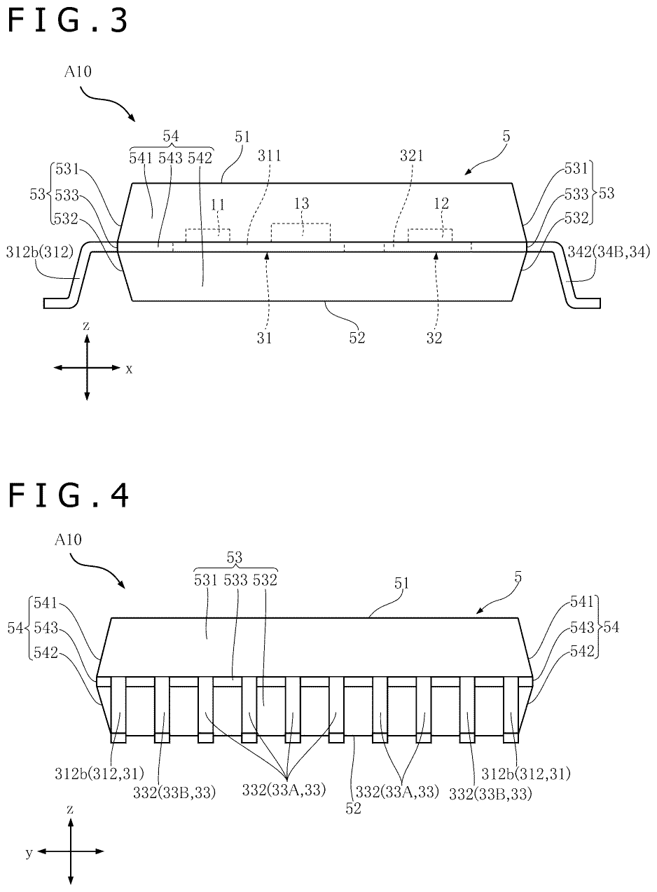

Each terminal part 312 includes a coated part 312a and an exposed part 312b. The coated part 312a is connected to the island part 311 and is covered with the sealing resin 5. The exposed part 312b is connected to the coated part 312a and is exposed from the sealing resin 5. The exposed part 312b extends along the first direction x in plan view. As can be understood from FIG. 3, the exposed part 312b is bent in a gull-wing shape when viewed in the second direction y. The surface of the exposed part 312b may be plated with, for example, tin (Sn).

The lead 32 includes an island part 321. The island part 321 has a loading surface 321a that faces one side (upward) in the third direction z. That is, the loading surface 321a faces the same direction as each main surface 12a. Each semiconductor element 12 is joined to the loading surface 321a via a conductive joining material 129. Each conductive joining material 129 is, for example, solder or metal paste or sintered metal. The island part 321 is covered with the sealing resin 5. In the illustrated example, the island part 321 has a rectangular shape in plan view. The thickness of the island part 321 is, for example, equal to or larger than 100 μm but equal to or smaller than 300 μm.

The lead 32 further includes two terminal parts 322. The two terminal parts 322 extend from both sides of the island part 321 in the second direction y. The two terminal parts 322 are separated from each other in the second direction y. At least one of the two terminal parts 322 is conductive to the ground of each semiconductor element 12.

Each terminal part 322 includes a coated part 322a and an exposed part 322b. The coated part 322a is connected to the island part 321 and is covered with the sealing resin 5. The exposed part 322b is connected to the coated part 322a and is exposed from the sealing resin 5. The exposed part 322b extends along the first direction x in plan view. As can be understood from FIG. 3, the exposed part 322b is bent in a gull-wing shape when viewed in the second direction y. The surface of the exposed part 312b may be plated with, for example, tin.

The plurality of leads 33 are positioned on the side opposite to the island part 321 with the island part 311 as a reference. The plurality of leads 33 are aligned along the second direction y. At least one of the plurality of leads 33 is conductive to the semiconductor element 11. The plurality of leads 33 include a plurality of (six in the illustrated example) intermediate leads 33A and two side leads 33B. The two side leads 33B are positioned on both sides of the plurality of intermediate leads 33A in the second direction y. Each side lead 33B is positioned between one of the two terminal parts 312 and the intermediate lead 33A positioned closest to the terminal part 312 in the second direction y. Unlike the illustrated example, the plurality of leads 33 may include those positioned on an outer side of either of the two terminal parts 312 of the lead 31.

Each lead 33 includes a coated part 331 and an exposed part 332. The coated part 331 is covered with the sealing resin 5. In the illustrated example, the dimension of each coated part 331 of the two side leads 33B in the first direction x is larger than the dimension of each coated part 331 of the plurality of intermediate leads 33A in the first direction x. The exposed part 332 is connected to the coated part 331 and is exposed from the sealing resin 5. The exposed part 332 extends along the first direction x in plan view. As can be understood from FIG. 7, the exposed part 332 is bent in a gull-wing shape when viewed along the second direction y. The shape of the exposed part 332 is equal to the shape of each exposed part 312b of the lead 31. The surface of the exposed part 332 may be plated with, for example, tin.

The plurality of leads 34 are positioned on the side opposite to the plurality of leads 33 with the island part 311 as a reference. The plurality of leads 34 are aligned along the second direction y. The plurality of leads 34 are conductive to each of the plurality of semiconductor elements 12. The plurality of leads 34 include a plurality of (six in the illustrated example) intermediate leads 34A and two side leads 34B. Each of the two side leads 34B is positioned on each of both sides of the plurality of intermediate leads 34A in the second direction y. In the second direction y, either of the two terminal parts 322 of the lead 32 is positioned between either of the two side leads 34B and the intermediate lead 34A positioned closest to the side lead 34B.

Each lead 34 includes a coated part 341 and an exposed part 342. The coated part 341 is covered with the sealing resin 5. In the illustrated example, the dimension of each coated part 341 of the two side leads 34B in the first direction x is larger than the dimension of each coated part 341 of the plurality of intermediate leads 34A in the first direction x. The exposed part 342 is connected to the coated part 341 and is exposed from the sealing resin 5. The exposed part 342 extends along the first direction x in plan view. As can be understood from FIG. 7, the exposed part 342 is bent in a gull-wing shape when viewed along the second direction y. The shape of the exposed part 342 is equal to the shape of each exposed part 322b of the lead 32. The surface of the exposed part 342 may be plated with, for example, tin. Unlike in the illustrated example, each of the two side leads 34B may be positioned between either of the two terminal parts 322 of the lead 32 and the intermediate lead 34A positioned closest to the terminal part 322 in the second direction y.

Each of the plurality of connecting members 4 allows two constitutional elements separated from each other to be conductive to each other. As depicted in FIGS. 1 and 2, the plurality of connecting members 4 include a plurality of wires 41 to 45. Each of the plurality of connecting members 4 is made of a metal material. The metal material includes, for example, gold, copper, or a copper alloy (for example, a palladium-copper alloy). Unlike in the illustrated example, each connecting member 4 may be a bonding ribbon or a plate-like metal member rather than a bonding wire. Alternatively, each connecting member 4 may include a core material (containing, for example, copper) and a surface layer part (for example, palladium) covering the core material.

Each wire 41 is joined to one of the plurality of pads 121 of each semiconductor element 12 and one of the plurality of pads 132 of the semiconductor element 13. Each wire 42 is joined to one of the plurality of pads 111 of the semiconductor element 11 and one of the plurality of pads 131 of the semiconductor element 13. Each wire 43 is joined to one of the plurality of pads 111 of the semiconductor element 11 and one coated part 312a of the two terminal parts 312. Each wire 44 is joined to one of the plurality of pads 111 of the semiconductor element 11 and one coated part 331 of the leads 33. Each wire 45 is joined to one of the plurality of pads 121 of each semiconductor element 12 and one coated part 341 of the leads 34. Each connection of the plurality of connecting members 4 in the drawing is an example and is not intended to limit the connection relation. Each connection of the plurality of connecting members 4 may be appropriately changed according to each configuration of the semiconductor device A10.

The plurality of wires 41 electrically connect the plurality of semiconductor elements 12 and the semiconductor element 13 to each other. The plurality of wires 41 are aligned along the second direction y. Each wire 41 is provided over the island part 311 of the lead 31 and the island part 321 of the lead 32 in plan view.

Each wire 41 includes joining parts 411 and 412 and a loop part 413. The joining part 411 is the end opposite to the joining part 412. The loop part 413 is connected to the joining part 411 and the joining part 412. FIG. 8 depicts one of the plurality of wires 41. The joining part 411 is positioned on the pad 132 of the semiconductor element 13. The joining part 412 is positioned on one pad 121 of the plurality of semiconductor elements 12. The loop part 413 extends from the joining part 411 toward the joining part 412 while being curved.

The plurality of wires 42 electrically connect the semiconductor element 11 and the semiconductor element 13 to each other. The plurality of wires 42 are aligned along the second direction y. Each wire 42 overlaps each through hole 313 in plan view.

Each wire 42 includes joining parts 421 and 422 and a loop part 423. The joining part 421 is the end opposite to the joining part 422. The loop part 423 is connected to the joining part 421 and the joining part 422. FIG. 8 depicts one of the plurality of wires 42. The loop part 423 is connected to the joining part 421 and the joining part 422. The joining part 421 is positioned on the pad 131 of the semiconductor element 13. The joining part 422 is positioned on the pad 111 of the semiconductor element 11. The loop part 423 extends from the joining part 421 toward the joining part 422 while being curved.

As depicted in FIG. 8, the topmost part of the wire 42 in the third direction z is positioned lower (closer to the island parts 311 and 321 in the third direction z) than the topmost part of the wire 41 in the third direction z. Alternatively, the topmost part of the wire 41 in the third direction z may be at the same position or may be positioned lower in the third direction z relative to the topmost part of the wire 42 in the third direction z.

The plurality of wires 43 electrically connect the semiconductor element 11 and the lead 31 to each other. In the present embodiment, one of the two terminal parts 312 is conductive to the ground of the semiconductor element 11 via the wire 43.

The plurality of wires 44 electrically connect the semiconductor element 11 and the plurality of leads 33 to each other. In other words, at least one of the plurality of leads 33 is conductive to the semiconductor element 11 via the wire 44.

The plurality of wires 45 electrically connect the plurality of semiconductor elements 12 and the plurality of leads 34 to each other. In other words, at least one of the plurality of leads 34 is conductive to one of the plurality of semiconductor elements 12 via the wire 45.

The semiconductor device A10 includes a first circuit including, as constitutional elements, the semiconductor element 11, the lead 31, the plurality of leads 33, the plurality of wires 42 through 44, and a part (each pad 131 and each lower winding 135b, for example) of the semiconductor element 13, and a second circuit including, as constitutional elements, the plurality of semiconductor elements 12, the lead 32, the plurality of leads 34, the plurality of wires 41 and 45, and a part (each pad 132 and each upper winding 135a, for example) of the semiconductor element 13. The plurality of semiconductor elements 12 require a power supply voltage higher than the power supply voltage required for the semiconductor element 11. Hence, a potential difference occurs between the semiconductor element 11 and each semiconductor element 12. That is, the first circuit and the second circuit are relatively different in potential. Specifically, the potential of the second circuit is higher than the potential of the first circuit. For example, in an inverter device of an electric vehicle or a hybrid vehicle, the voltage applied to the grounds of the semiconductor elements 12 may transiently become 600 V or more, whereas the voltage applied to the ground of the semiconductor element 11 is approximately 0 V. Depending on the specifications of the inverter device, the voltage applied to the grounds of the semiconductor elements 12 may become 3750 V or more. The first circuit and the second circuit are insulated from each other by the semiconductor element 13. Yet, the semiconductor element 13 can relay mutual signals in the first circuit and the second circuit.

The sealing resin 5 covers a part of the conductive support 3, the semiconductor element 11, the plurality of semiconductor elements 12, the semiconductor element 13, and the plurality of connecting members 4 as depicted in FIG. 1. The sealing resin 5 has electrical insulation. The sealing resin 5 insulates the constitutional element (for example, the lead 31) of the first circuit and the constitutional element (for example, the lead 32) of the second circuit from each other. The sealing resin 5 is made of a material containing, for example, black epoxy resin. In the illustrated example, the sealing resin 5 has a rectangular shape in plan view.

As depicted in FIGS. 2 through 5, the sealing resin 5 has a top surface 51, a bottom surface 52, two side surfaces 53, and two side surfaces 54. The top surface 51 and the bottom surface 52 are separated from each other in the third direction z. Each of the top surface 51 and the bottom surface 52 is substantially flat. The two side surfaces 53 are connected to the top surface 51 and the bottom surface 52 and are separated from each other in the first direction x. The two side surfaces 54 are connected to the top surface 51 and the bottom surface 52 and are separated from each other in the second direction y.

Each exposed part 312b of the two terminal parts 312 and each exposed part 332 of the plurality of leads 33 are exposed from one side surface 53 of the two side surfaces 53. Each exposed part 322b of the two terminal parts 322 and each exposed part 342 of the plurality of leads 34 are exposed from the other side surface 53 of the two side surfaces 53. Each of the two side surfaces 53 includes an upper part 531, a lower part 532, and an intermediate part 533. One side of the upper part 531 in the third direction z is connected to the top surface 51, and the other side thereof in the third direction z is connected to the intermediate part 533. The upper part 531 is inclined relative to the top surface 51. One side of the lower part 532 in the third direction z is connected to the bottom surface 52, and the other side thereof in the third direction z is connected to the intermediate part 533. The lower part 532 is inclined relative to the bottom surface 52. One side of the intermediate part 533 in the third direction z is connected to the upper part 531, and the other side thereof in the third direction z is connected to the lower part 532. The in-plane directions of the intermediate part 533 are the third direction z and the second direction y. The intermediate part 533 is positioned on an outer side than the top surface 51 and the bottom surface 52 in plan view. The exposed parts 312b of the two terminal parts 312 (the lead 31), the exposed parts 322b of the two terminal parts 322 (the lead 32), the exposed parts 332 of the plurality of leads 33, and the exposed parts 342 of the plurality of leads 34 project from the intermediate parts 533 of the two side surfaces 53.

The two side surfaces 54 do not expose any lead. Each of the two side surfaces 54 includes an upper part 541, a lower part 542, and an intermediate part 543. One side of the upper part 541 in the third direction z is connected to the top surface 51, and the other side thereof in the third direction z is connected to the intermediate part 543. The upper part 541 is inclined relative to the top surface 51. One side of the lower part 542 in the third direction z is connected to the bottom surface 52, and the other side thereof in the third direction z is connected to the intermediate part 543. The lower part 542 is inclined relative to the bottom surface 52. One side of the intermediate part 543 in the third direction z is connected to the upper part 541, and the other side thereof in the third direction z is connected to the lower part 542. The in-plane directions of the intermediate part 543 are the third direction z and the second direction y. The intermediate part 543 is positioned on an outer side than the top surface 51 and the bottom surface 52 in plan view.

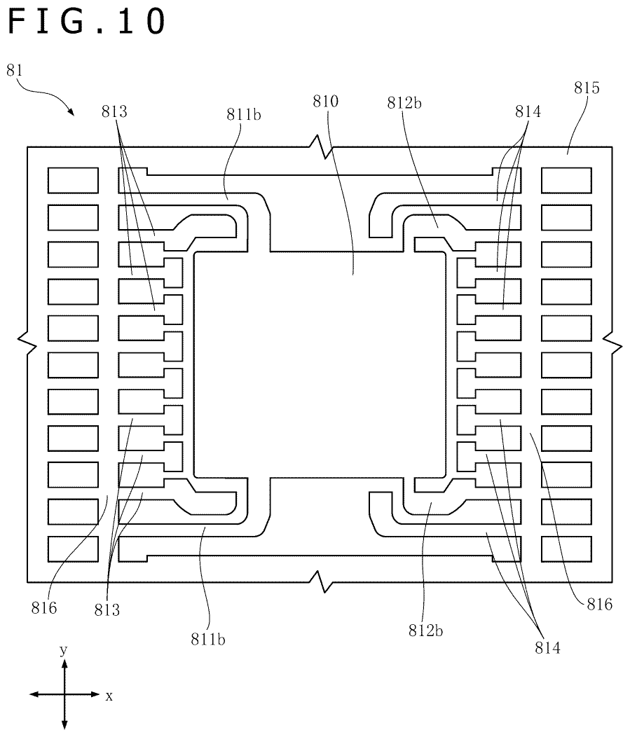

Next, an example of a manufacturing method of the semiconductor device A10 will be described with reference to FIGS. 10 through 15. The manufacturing method of the semiconductor device A10 includes a lead frame preparation step, a lead frame processing step, an element loading step, a wire bonding step, a sealing step, and a singulating step.

First, the lead frame preparation step depicted in FIG. 10 is performed. In the lead frame preparation step, a lead frame 81 is prepared. The lead frame 81 includes a flat plate part 810, a plurality of supporting leads 811b and 812b, a plurality of leads 813 and 814, an outer frame 815, and a dam bar 816. The lead frame 81 is formed, for example, by punching a copper plate having a rectangular shape in plan view. The plurality of supporting leads 811b and 812b are connected to the flat plate part 810 and the dam bar 816. The plurality of leads 813 and 814 are connected to the dam bar 816. The dam bar 816 is connected to the outer frame 815. Therefore, the plurality of supporting leads 811b and 812b and the plurality of leads 813 and 814 are connected to each other via the outer frame 815 and the dam bar 816. In the lead frame 81, the outer frame 815 and the dam bar 816 do not configure the semiconductor device A10. The lead frame 81 is made of, for example, copper or a copper alloy.

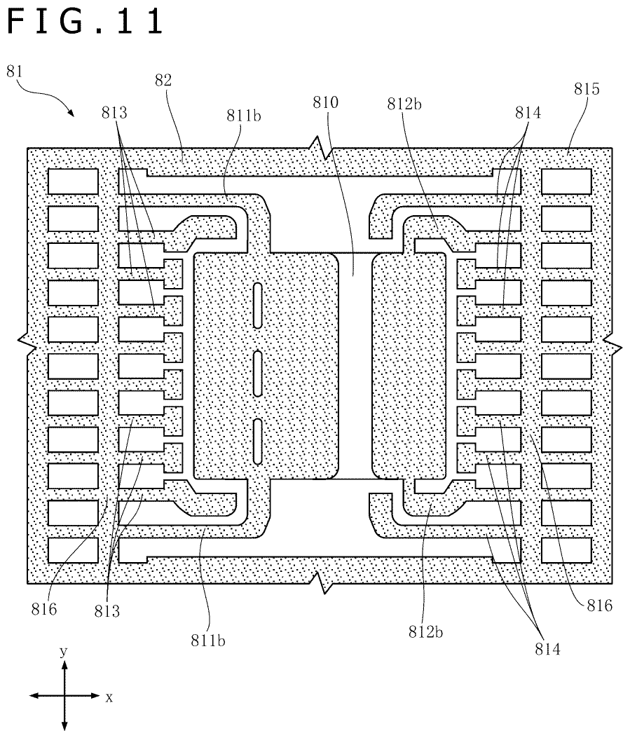

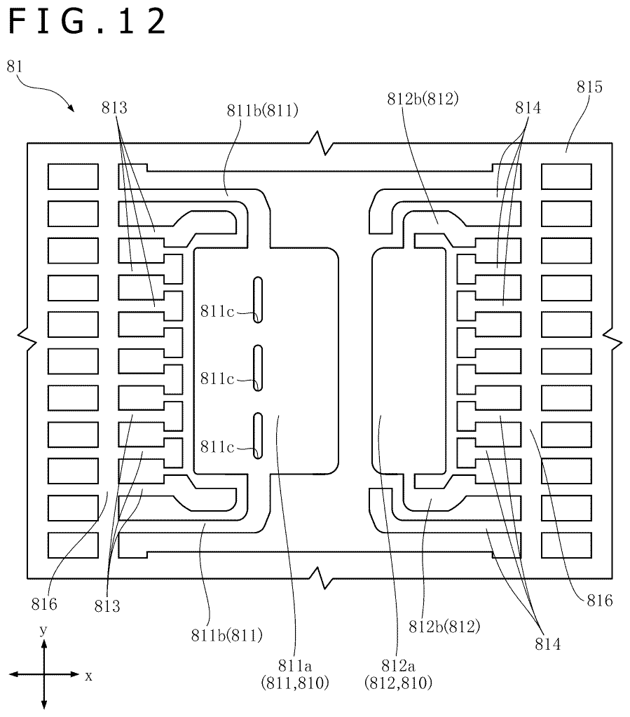

Next, the lead frame processing step depicted in FIGS. 11 and 12 is performed. In the lead frame processing step, a resist 82 is first formed on the lead frame 81 as depicted in FIG. 11. In FIG. 11, dots are drawn on the resist 82. Then, an etching process is applied to the lead frame 81 on which the resist 82 is formed. Accordingly, a portion of the lead frame 81 exposed from the resist 82 is removed, the flat plate part 810 is divided into two islands 811a and 812a, and a plurality of through holes 811c are formed in the flat plate part 810 (island 811a). Thereafter, the resist 82 is removed to form the lead frame 81 depicted in FIG. 12. A lead 811 and a lead 812 are formed in the lead frame 81. The lead 811 includes the island 811a and a plurality of supporting leads 811b each of which is connected to the island 811a. The lead 812 includes an island 812a and a plurality of supporting leads 812b each of which is connected to the island 812a. Thus, in the lead frame processing step, the flat plate part 810 of the lead frame 81 is divided into the two islands 811a and 812a.

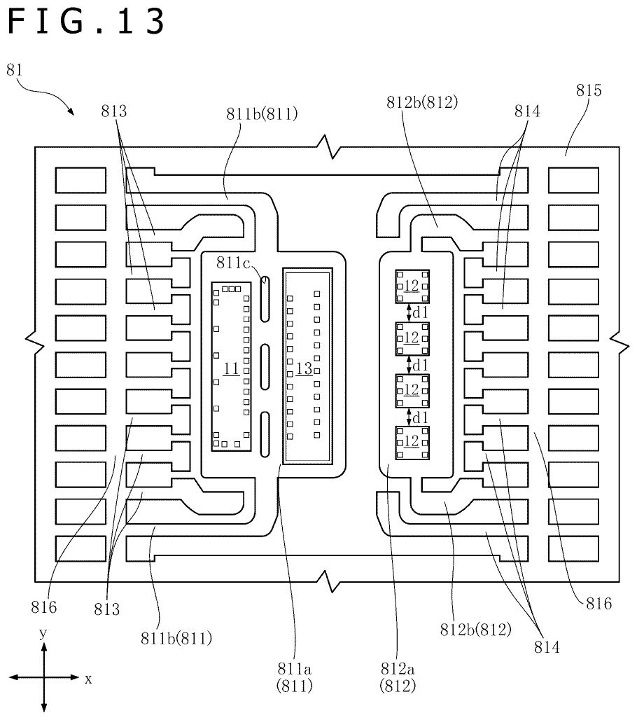

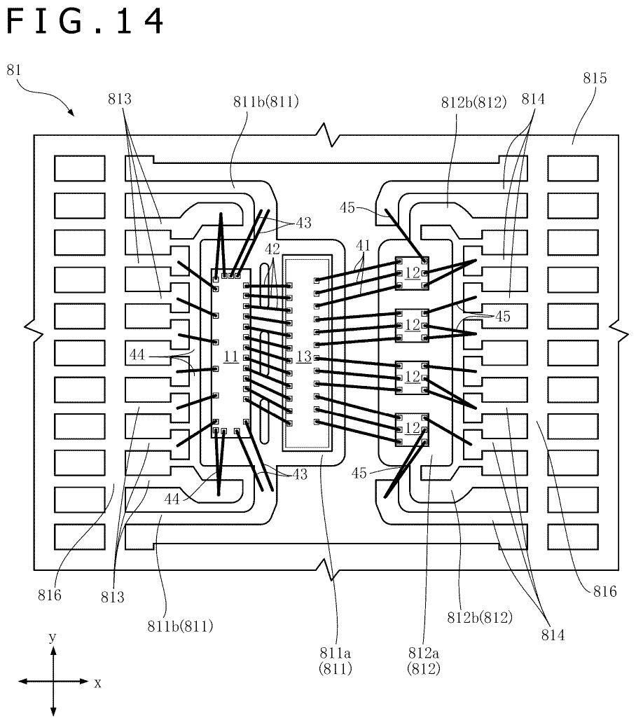

Subsequently, the element loading step depicted in FIG. 13 is performed. In the element loading step, three semiconductor elements 11, 12, and 13 are prepared and loaded on the lead frame 81. Specifically, each of the two semiconductor elements 11 and 13 is joined to the island 811a by an unillustrated conductive joining material, and the plurality of semiconductor elements 12 are joined to the island 812a by an unillustrated conductive joining material. The plurality of semiconductor elements 12 are arranged at intervals d1 in the second direction y.

Thereafter, the wire bonding step depicted in FIG. 14 is performed. In the wire bonding step, the plurality of wires 41 to 45 are formed. Each of the wires 41 through 45 may be formed using a well-known wire bonder. The wires 41 and 42 may be formed by, for example, ball bonding. In this case, each wire 41 is first bonded to one of the plurality of pads 132 to form a joining part 411 and then second bonded to a corresponding one of the plurality of pads 121 to form a joining part 412. Similarly, each wire 42 is first bonded to a corresponding one of the plurality of pads 131 to form a joining part 421 and second bonded to one of the plurality of pads 111 to form a joining part 422. The other wires 43 through 45 may be similarly formed. Alternatively, each of the wires 41 through 45 may be formed by another method such as wedge bonding. The order of formation of the respective wires 41 through 45 is not particularly limited to any specific order.

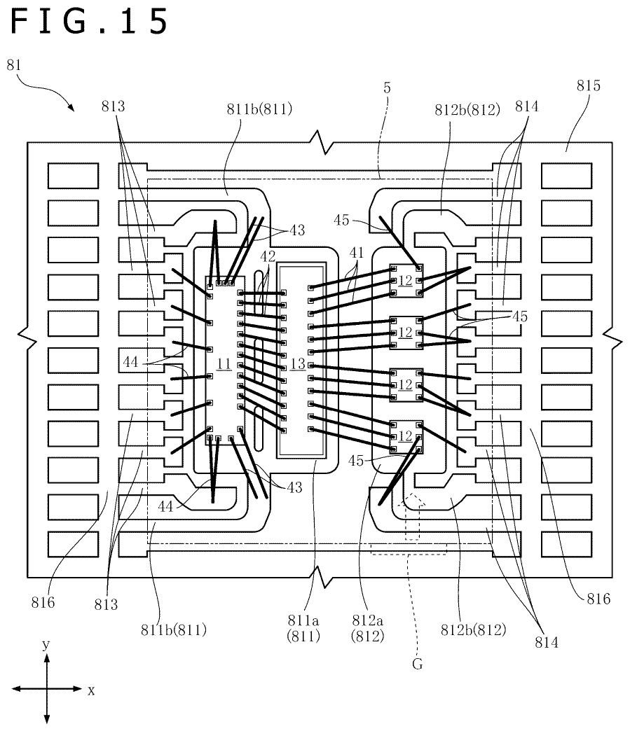

Next, the sealing step depicted in FIG. 15 is performed. In the sealing step, the sealing resin 5 is formed. The sealing resin 5 is formed by transfer molding. Specifically, molten resin is poured from an inflow port G to fill and form the sealing resin 5. In FIG. 15, the sealing resin 5 is indicated by an imaginary line (two-dot chain line), and the inflow port G is indicated by a dotted line. The inflow port G is positioned near (that is, lower right of FIG. 15) the lowermost lead 814. Alternatively, the inflow port G may be positioned near (that is, lower left of FIG. 15) the lowermost lead 813. The inflow port G is at the same position as the island 812a in the first direction x. The inflow port G may be positioned below the island 812a in the third direction z.

Finally, the semiconductor device A10 is manufactured by performing the singulating step. In the singulating step, the singulation is performed by dicing. Specifically, the plurality of leads 811, 812, 813, and 814 connected to each other by the outer frame 815 and the dam bar 816 are appropriately separated from each other. The leads 33, 32, 33, and 34 are formed from the leads 811, 812, 813, and 814, respectively. The island 811a becomes the island part 311, and each supporting lead 811b becomes each terminal part 312. The island 812a becomes the island part 321, and each supporting lead 812b becomes each terminal part 322. The plurality of leads 33 (the plurality of leads 813) and the plurality of leads 34 (the plurality of leads 814) may be bent during the singulating step or the punching process in the lead frame preparation step.

The manufacturing method of the semiconductor device A10 is not limited to the above example. For example, by forming the two islands 811a and 812a by the punching process in the lead frame preparation step, the lead frame processing step need not be performed. In addition, for example, a copper plate having a rectangular shape in plan view may be prepared in the lead frame preparation step, and the lead 811 (the island 811a and the plurality of supporting leads 811b), the lead 812 (the island 812a and the plurality of supporting leads 812b), the plurality of leads 813 and 814, the outer frame 815, and the dam bar 816 may be integrally formed from the prepared copper plate by forming and etching the resist 82 in the lead frame processing step.

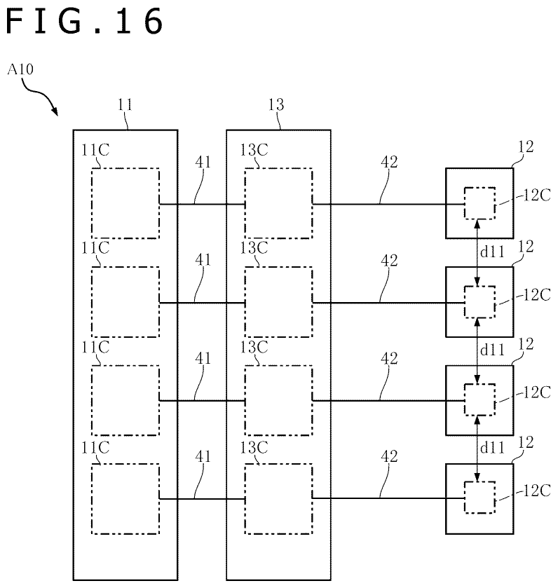

Next, an example of an electrical configuration of the semiconductor device A10 will be described with reference to FIG. 16. FIG. 16 schematically illustrates the semiconductor element 11, the plurality of semiconductor elements 12, the semiconductor element 13, the plurality of wires 41, and the plurality of wires 42. Further, FIG. 16 illustrates the electrical configurations of the respective semiconductor elements 11, 12, and 13 by imaginary lines (two-dot chain lines).

The semiconductor element 11 and the semiconductor element 13 include electrical configurations the number of which is the same as the plurality of semiconductor elements 12. In the illustrated example, the semiconductor element 11 includes four circuits 11C, each of the four semiconductor elements 12 includes one circuit 12C, and the semiconductor element 13 includes four circuits 13C. The four circuits 11C are electrically connected to the respective four circuits 12C via the corresponding wires 41, the corresponding wires 42, and the four circuits 13C. That is, the semiconductor device A10 may include a plurality of physically independent electrical configurations according to the number of the plurality of semiconductor elements 12. In the example depicted in the drawing, two adjacent circuits 12C are arranged at an interval d11.

The actions and effects of the semiconductor device A10 are as follows.

The semiconductor device A10 is advantageous in reducing interference among a plurality of circuits. Typically, in a semiconductor device provided with a plurality of semiconductor elements, there is a possibility that interference among circuits occurs in the case where a distance between the electrical contacts of the semiconductor elements is not sufficient. In contrast, in the semiconductor device A10, the plurality of semiconductor elements 12 are different from the semiconductor element 11 in potential and are separated from each other in such a manner as to be aligned along the second direction y. According to such a configuration, a short circuit between the electrical contacts of the plurality of semiconductor elements 12 can be reliably prevented. That is, such a configuration is advantageous in reducing interference among the circuits.

Each of the plurality of semiconductor elements 12 includes the circuit 12C. A part of the sealing resin 5 is interposed between adjacent circuits 12C. Accordingly, the insulation between adjacent circuits 12C can be further increased, and the interval d11 can be reduced. For example, in a configuration in which a plurality of circuits 12C are included in one semiconductor element 12 unlike in the present example, two adjacent circuits 12C may be connected to each other by a semiconductor material. In this case, in order to appropriately secure the insulation between two adjacent circuits 12C, the interval between them may be required to be larger than the interval d11. Thus, the semiconductor device A10 can be downsized.

The semiconductor device A10 is advantageous in downsizing. In a semiconductor device provided with two leads having a potential difference, in the case where a semiconductor element is provided on one of the leads, a method of reducing the dielectric breakdown by forming the element large has been adopted from the past. In contrast, the semiconductor device A10 includes the plurality of semiconductor elements 12 separated from each other on the lead 32. Thus, the distance between the plurality of semiconductor elements 12 can be shortened, and the lead 32 can be downsized. Accordingly, such a configuration can downsize the semiconductor device A10.

The semiconductor element 11 and the semiconductor element 13 include the plurality of circuits 11C and 13C corresponding to the number of the plurality of semiconductor elements 12, respectively. The circuits 11C of the semiconductor element 11 may be electrically connected to one circuit 12C of the plurality of semiconductor elements 12. In such a configuration, for example, an electrical signal via each lead 33 is individually transmitted from the semiconductor element 11 to one of the plurality of semiconductor elements 12 through the semiconductor element 13. This means that an electrical signal can be independently transmitted via each of the plurality of semiconductor elements 12. Compared with the case where such a circuit configuration is realized by one semiconductor element 12, since the sealing resin 5 is interposed between the plurality of semiconductor elements 12 in the semiconductor device A10, electrical signals are more reliably divided between the plurality of semiconductor elements 12. Therefore, the plurality of semiconductor elements 12 can be brought close to each other. Thus, such a configuration is advantageous in downsizing.

Next, other embodiments and modified examples of the semiconductor device of the present disclosure will be described. The configurations of the respective parts in the respective embodiments and the respective modified examples can be combined with each other to the extent that no technical inconsistency occurs. In the following description, the same or similar constitutional elements will be denoted by the same reference numerals and repeated descriptions will appropriately be omitted. In addition, the description of the manufacturing methods of the semiconductor devices according to other embodiments and modified examples will appropriately be omitted. The semiconductor devices according to other embodiments and modified examples can be manufactured by the method similar to that of the semiconductor device A10 in consideration of common general technical knowledge.

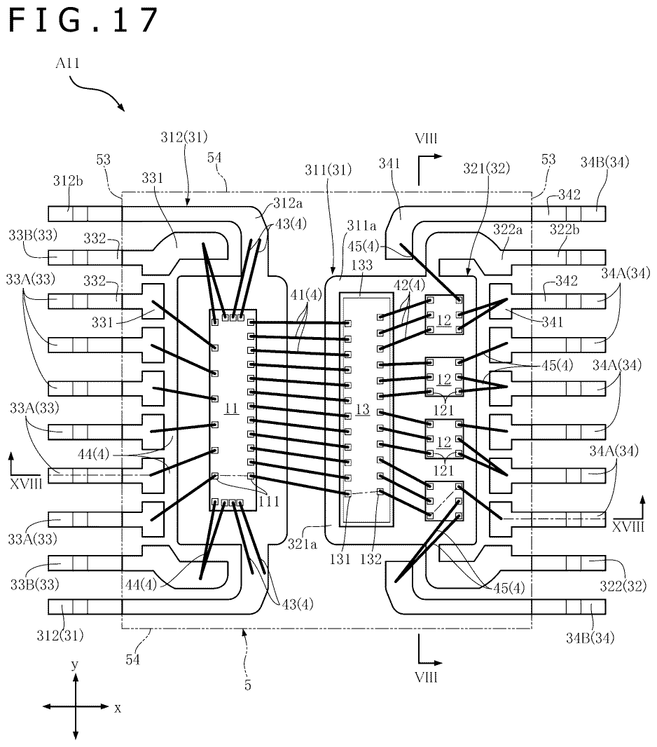

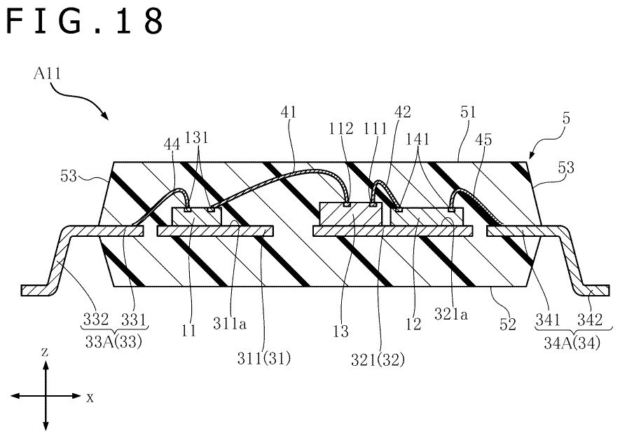

FIGS. 17 and 18 depict a semiconductor device A11 according to a first modified example of the first embodiment. The semiconductor device A11 differs from the semiconductor device A10 in the position of the semiconductor element 13. Specifically, the semiconductor element 13 is loaded on the lead 32 (the island part 321) in the semiconductor device A11, whereas the semiconductor element 13 is arranged on the lead 31 (the island part 311) in the semiconductor device A10.

In the semiconductor device A11, the semiconductor element 13 is joined to the island part 321 by the conductive joining material 139. In this configuration, the semiconductor substrate 130 and the seal ring part 133 of the semiconductor element 13 have the same potential as that of the lead 32. That is, the seal ring part 133 has the same potential as that of the second circuit.

Each wire 41 is provided over the lead 31 and the lead 32. In the semiconductor device A11, the semiconductor element 13 is loaded on the lead 32 unlike in the semiconductor device A10, so that the seal ring part 133 has the same potential as that of the island part 321 and may be a constitutional element of the second circuit. Meanwhile, since each wire 41 is conductive to the semiconductor element 11, it has the same potential as that of the semiconductor element 11 and remains as a constitutional element of the first circuit. That is, the seal ring part 133 is relatively high in potential and each wire 41 is relatively low in potential, and thus, a potential difference occurs between the seal ring part 133 and each wire 41.

In the semiconductor device A11, the semiconductor element 13 is joined to the island part 321 by the conductive joining material 139. In this configuration, the semiconductor substrate 130 and the seal ring part 133 have the same potential as that of the lead 32 in the semiconductor element 13. That is, the seal ring part 133 has the same potential as that of the second circuit.

Similarly to the semiconductor device A10, the semiconductor device A11 is advantageous in reducing the occurrence of dielectric breakdown. As can be understood from the present modified example, the semiconductor element 13 may be loaded on either the lead 31 or the lead 32 in the semiconductor device of the present disclosure.

### Second Embodiment

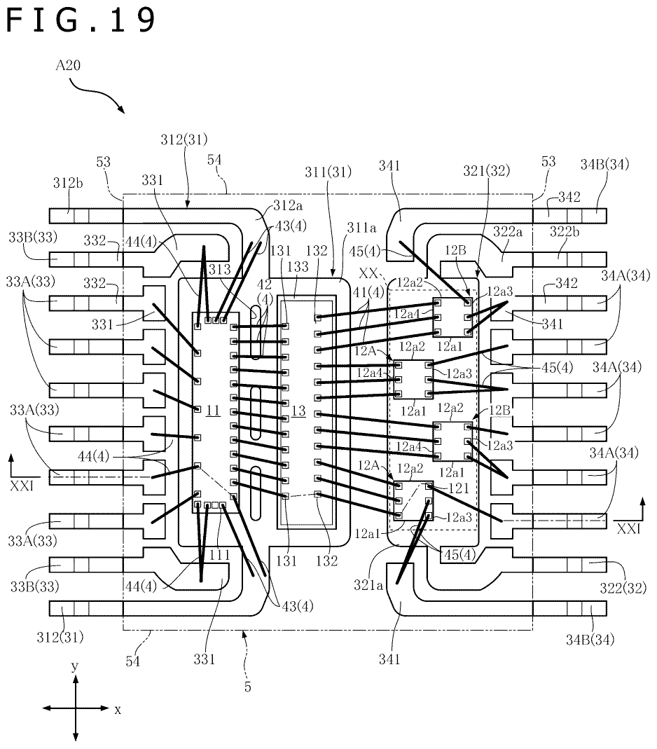

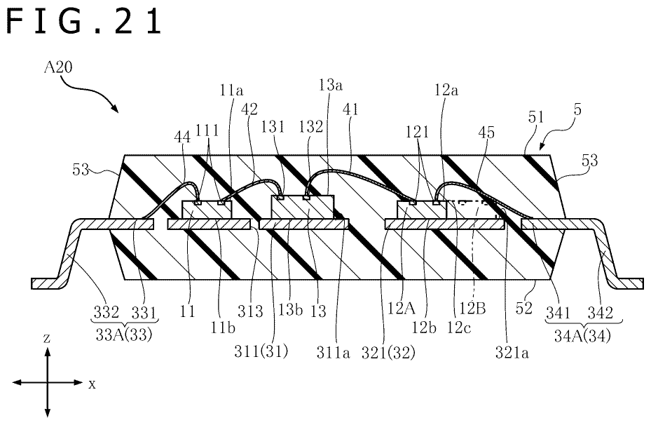

FIGS. 19 through 21 depict a semiconductor device A20 according to a second embodiment. The semiconductor device A20 differs from the semiconductor device A10 in the arrangement of the plurality of semiconductor elements 12.

In the present embodiment, the plurality of semiconductor elements 12 include a plurality of semiconductor elements 12A arranged in a first column and a plurality of semiconductor elements 12B arranged in a second column separated from the first column in the first direction x. The first column is closer to the lead 31 than the second column. The “column” means an arrangement of a group of elements aligned in a fixed direction among a plurality of elements. In the illustrated example, the first column and the second column are in a linear shape parallel to the second direction y. Alternatively, the first column and the second column need not be parallel to the second direction y and may be curved. Further, the number of columns in which the plurality of semiconductor elements 12 are arranged may be two or more. The number of semiconductor elements 12 arranged in the first column or the second column is not particularly limited to any number, but two semiconductor elements 12A and two semiconductor elements 12B are provided in the illustrated example. Alternatively, the number of semiconductor elements arranged in the first column or the second column may be one.

The plurality of semiconductor elements 12A are regularly arranged between the plurality of semiconductor elements 12B. Specifically, the plurality of semiconductor elements 12A may be arranged point-symmetrically with respect to the plurality of semiconductor elements 12B. In the illustrated example, the plurality of semiconductor elements 12 are arranged in zigzag. The “arrangement in zigzag” means an arrangement of a plurality of elements in which adjacent columns are alternately offset. That is, the plurality of semiconductor elements 12A arranged in the first column are positioned between the plurality of semiconductor elements 12B arranged in the second column in the second direction y. Two adjacent semiconductor elements 12 do not face each other in the second direction y. In the illustrated example, the plurality of semiconductor elements 12 are arranged at intervals d1 in the second direction y. The interval d1 corresponds to a distance along the second direction y between the extension of the first side 12a1 and the second side 12a2 of two adjacent semiconductor elements 12 (that is, between the semiconductor element 12A and the semiconductor element 12B). The distance between the semiconductor element 12A and the semiconductor element 12B that are adjacent to each other in the second direction y may be irregular.

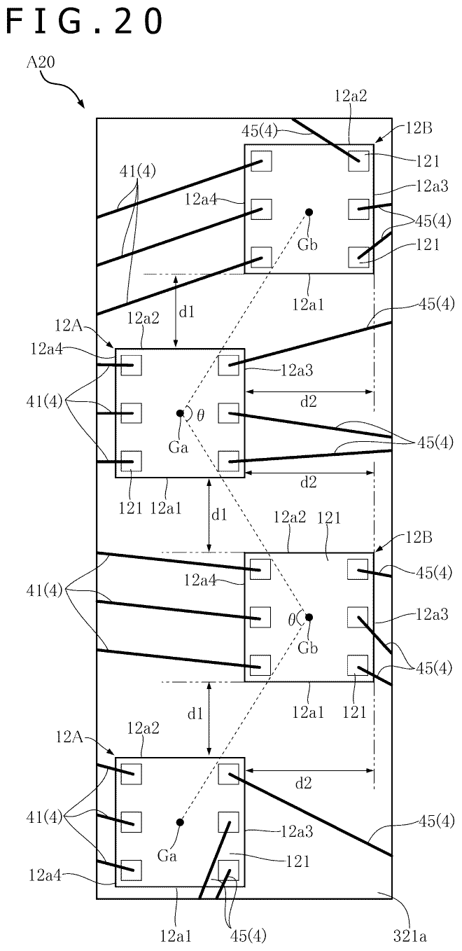

Each semiconductor element 12 includes the third side 12a3 at a position farthest from the lead 31. The third side 12a3 of each semiconductor element 12A is separated from the extension of the third side 12a3 of each semiconductor element 12B by an interval d2 along the first direction x. Described with reference to FIG. 20, the interval d2 is illustrated. In the case where the plurality of semiconductor elements 12 are linearly arranged along the second direction y as in the semiconductor device A10, there is a possibility that an arrangement error occurs in the first direction x for each of the plurality of semiconductor elements 12. The interval d2 is preferably larger than such an error. For example, the interval d2 is equal to or larger than 50 μm. In other words, the end of the semiconductor element 12A in the first direction x is separated from the end of the semiconductor element 12B in the first direction x by 50 μm or more along the first direction x. All the distances along the first direction x between the plurality of semiconductor elements 12A and the plurality of semiconductor elements 12B may be equal.

Each semiconductor element 12 includes the fourth side 12a4 at a position closest to the lead 31. In the illustrated example, the fourth side 12a4 of each semiconductor element 12B overlaps the third side 12a3 of each semiconductor element 12A when viewed in the second direction y. Alternatively, the fourth side 12a4 of each semiconductor element 12B need not overlap the third side 12a3 of each semiconductor element 12A when viewed in the second direction y.

In FIGS. 19 and 20, first geometrical centers of gravity Ga of the plurality of semiconductor elements 12A when viewed in the third direction z and second geometrical centers of gravity Gb of the plurality of semiconductor elements 12B when viewed in the third direction z are illustrated. In the semiconductor device A20, the first geometrical center of gravity Ga is positioned obliquely to the second geometrical center of gravity Gb in plan view. Hence, the distance between the geometrical centers of gravity of the plurality of semiconductor elements 12 is larger in the semiconductor device A20 than that in the semiconductor device A10. Optionally, the first geometrical centers of gravity Ga of the plurality of semiconductor elements 12A may be aligned in the first direction x. Further, the second geometrical centers of gravity Gb of the plurality of semiconductor elements 12B may be aligned in the first direction x.

Further, angles θ are illustrated in FIG. 20. The angle θ corresponds to an angle formed by line segments connecting two second geometrical centers of gravity Gb of the plurality of semiconductor elements 12B to one of the first geometrical centers of gravity Ga of the plurality of semiconductor elements 12A. Alternatively, the angle θ corresponds to an angle formed by line segments connecting two first geometrical centers of gravity Ga of the plurality of semiconductor elements 12A to one of the second geometrical centers of gravity Gb of the plurality of semiconductor elements 12B. The angle θ is, for example, equal to or larger than 30° but equal to or smaller than 330°. The semiconductor device A10 according to the first embodiment corresponds to a case where the angle θ is 180°. The semiconductor device A20 according to the second embodiment corresponds to a case where the angle θ is equal to or larger than 30° but smaller than 180°.

The actions and effects of the semiconductor device A20 are as follows.

Similarly to the semiconductor device A10, the semiconductor device A20 is configured such that the plurality of semiconductor elements 12 are separated from each other in such a manner as to be aligned along the second direction y, and thus is advantageous in reducing the occurrence of dielectric breakdown.

The semiconductor device A20 can reduce the occurrence of voids in the sealing resin 5. The voids in the sealing resin 5 contribute to dielectric breakdown. The semiconductor device A20 includes the plurality of semiconductor elements 12A arranged in the first column and the plurality of semiconductor elements 12B arranged in the second column separated from the first column in the first direction x. According to such a configuration, when the semiconductor device A20 is manufactured, the resin poured from the inflow port G easily flows around the plurality of semiconductor elements 12. This is because the resin easily enters a portion between the first side 12a1 and the second side 12a2 of two adjacent semiconductor elements 12. As a result, since bubbles are less likely to remain in the vicinity of the plurality of semiconductor elements 12, the occurrence of the voids in the sealing resin 5 is reduced. Thus, the semiconductor device A20 is more advantageous in reducing the occurrence of dielectric breakdown.

The semiconductor device A20 can reduce the wire flow of the wire 45. The semiconductor element 12 closest to the inflow port G among the plurality of semiconductor elements 12 in the semiconductor device A20 is closer to the tip of one of the two side leads 34B as compared that in the semiconductor device A10. Thus, the distance between the pad 121 of the semiconductor element 12 and the coated part 341 of the side lead 34B becomes smaller. As a result, in the wire 45 joined to the pad 121 and the coated part 341, a component extending in the first direction x is reduced. Hence, the direction in which the wire 45 extends tends to be parallel to the flow of the resin. Accordingly, the influence of the poured resin on the wire 45 is reduced, and the possibility of the occurrence of a failure in the wire 45 can be reduced.

Each semiconductor element 12A includes the third side 12a3 at a position farthest from the lead 31, and each semiconductor element 12B includes the third side 12a3 at a position farthest from the lead 31. The third side 12a3 of each semiconductor element 12A may be separated from the third side 12a3 of each semiconductor element 12B by 50 μm or more along the first direction. Such a configuration is more advantageous in reducing the occurrence of dielectric breakdown since the distance between each semiconductor element 12A and each semiconductor element 12B is secured.

Each semiconductor element 12B includes the fourth side 12a4 closest to the lead 31. The fourth side 12a4 of each semiconductor element 12B need not overlap the third side 12a3 of each semiconductor element 12A when viewed in the second direction y. This means that there is a gap between each semiconductor element 12A and each semiconductor element 12B in the first direction x. The gap allows the resin flowing from the inflow port G toward the plurality of semiconductor elements 12 to spread more smoothly in the second direction y. As a result, since bubbles are less likely to remain in the vicinity of the plurality of semiconductor elements 12, the occurrence of the voids in the sealing resin 5 is reduced. Thus, such a configuration is more advantageous in reducing the occurrence of dielectric breakdown.

The plurality of semiconductor elements 12B may include a semiconductor element 12B positioned in the second direction y between two semiconductor elements 12A arranged in the first column. That is, the first side 12a1 and the second side 12a2 need not face each other in both of two adjacent semiconductor elements 12. This makes it easier for the resin to enter between the first side 12a1 and the second side 12a2 of the two adjacent semiconductor elements 12. Therefore, such a configuration can further reduce the occurrence of the voids in the sealing resin 5.

Each semiconductor element 12A may include the first geometrical center of gravity Ga when viewed in the third direction z, and the first geometrical centers of gravity Ga may be aligned in the first direction x. According to such a configuration, since it becomes easy to densely arrange the plurality of semiconductor elements 12 in the second direction y, the dimension of the semiconductor device A20 in the second direction y can be reduced.

Further, each semiconductor element 12B may include the second geometrical center of gravity Gb when viewed in the third direction z, and the second geometrical centers of gravity Gb may be aligned in the first direction x. According to such a configuration, since the plurality of semiconductor elements 12 are regularly arranged in two columns in the first direction x, heat from the plurality of semiconductor elements 12 can efficiently be dispersed.

The plurality of semiconductor elements 12A may be arranged point-symmetrically with respect to the plurality of semiconductor elements 12B. According to such a configuration, it is possible to reduce unbalanced arrangement of the plurality of semiconductor elements 12 on the island part 321. This is advantageous in making the lead 32 difficult to deform.

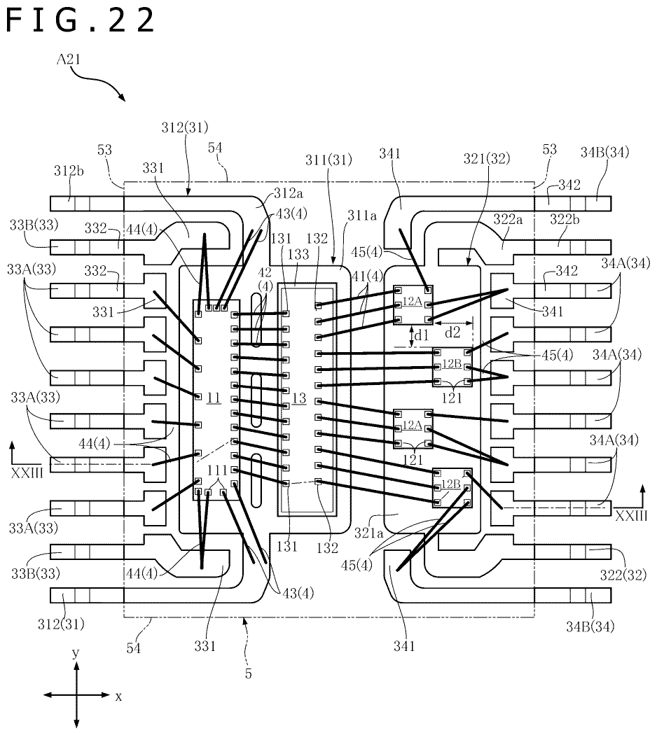

FIGS. 22 and 23 depict a semiconductor device A21 according to a first modified example of the second embodiment. The semiconductor device A21 differs from the semiconductor device A20 in the arrangement of the plurality of semiconductor elements 12. Specifically, the arrangement of the plurality of semiconductor elements 12 in zigzag is reversed. More specifically, the positions of the first column (the plurality of semiconductor elements 12A) and the second column (the plurality of semiconductor elements 12B) in the first direction x are switched. That is, the second column is closer to the lead 31 than the first column. This corresponds to a case where the above-described angle θ is larger than 180° but equal to or smaller than 330°.

The semiconductor device A21 exhibits effects similar to those of the semiconductor device A20. For example, the semiconductor device A21 is advantageous in reducing the occurrence of dielectric breakdown. As can be understood from the present modified example, the arrangement of each semiconductor element 12A and each semiconductor element 12B in the semiconductor device of the present disclosure is not particularly limited to any specific arrangement.

In the case where the examples depicted in the semiconductor device A20 and the semiconductor device A21 are included in the description of the claims, the terms may correspond to the following. The lead 31, the lead 32, and the lead 34 correspond to a “first lead,” a “second lead,” and a “third lead,” respectively. Further, the semiconductor element 11 and the plurality of semiconductor elements 12 may correspond to “at least one first semiconductor element” and “a plurality of second semiconductor elements,” respectively. Further, the pad 121 may correspond to a “first pad.” Further, the third side 12a3 of the semiconductor element 12A, the third side 12a3 of the semiconductor element 12B, and the fourth side 12a4 of the semiconductor element 12A may correspond to a “first end,” a “second end,” and a “third end,” respectively. Further, the wire 45 and the wire 41 may correspond to a “first wire” and a “second wire,” respectively. In addition, the pad 132, the pad 131, and the seal ring part 133 may correspond to a “second pad,” a “third pad,” and a “seal ring part,” respectively.

### Third Embodiment

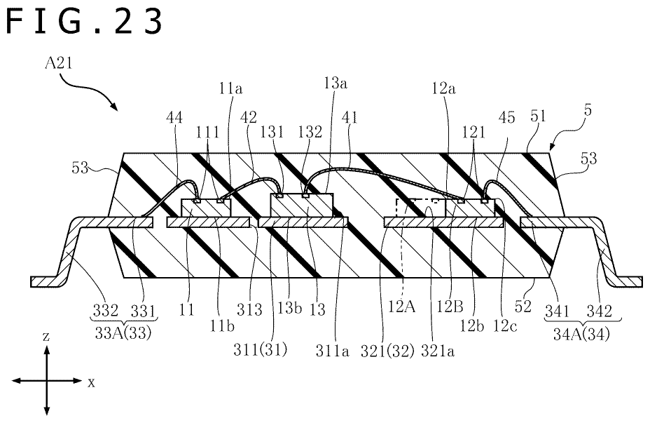

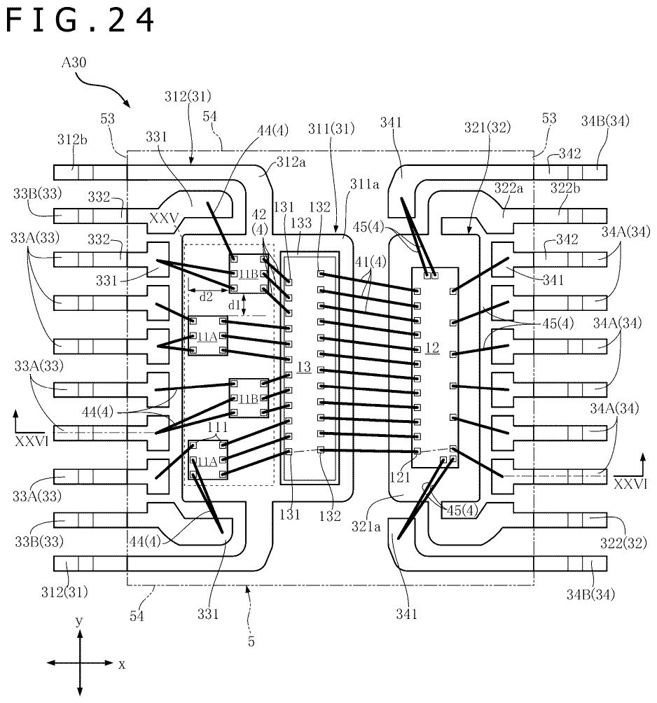

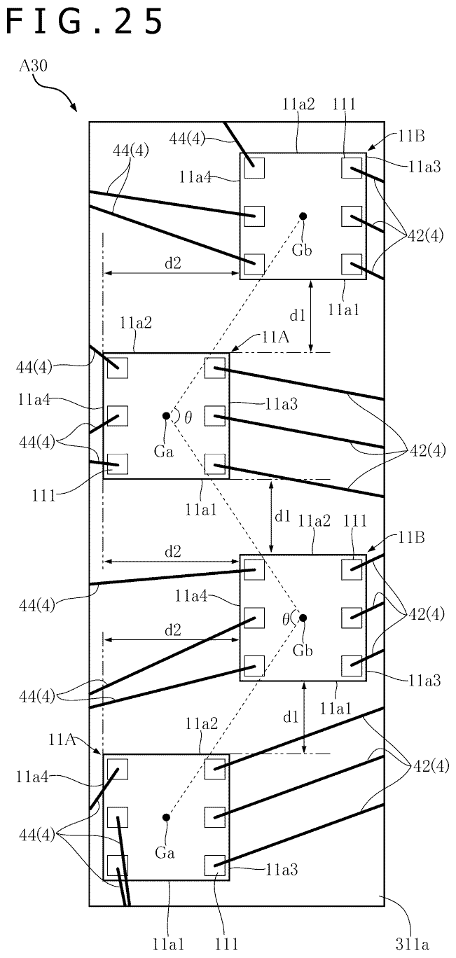

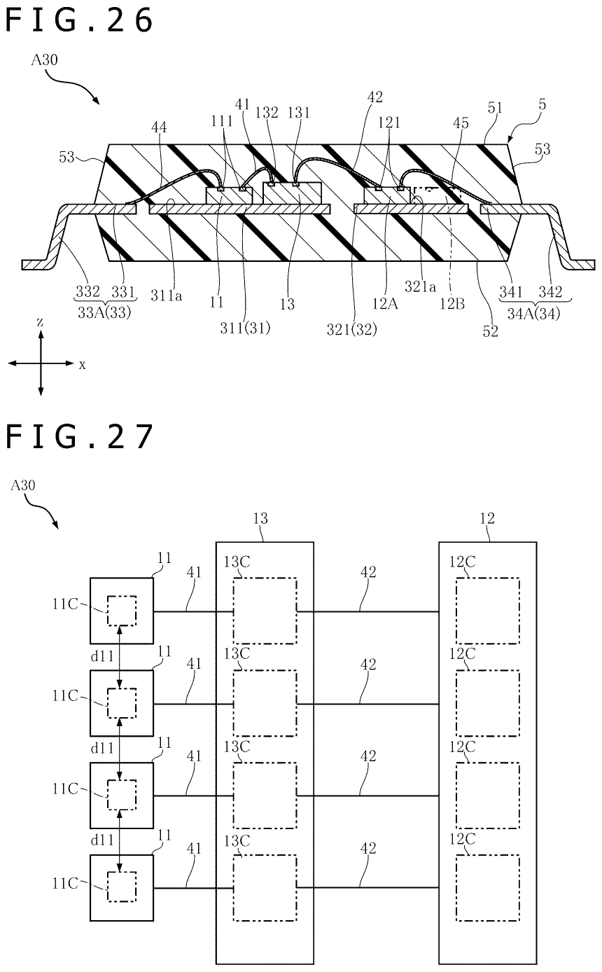

FIGS. 24 through 27 depict a semiconductor device A30 according to a third embodiment. The semiconductor device A30 differs from the semiconductor device A10 and the semiconductor device A20 in the configurations of the plurality of semiconductor elements 11, 12, and 13. Specifically, the semiconductor device A30 includes a plurality of semiconductor elements 11 arranged in zigzag on a lead 31, one semiconductor element 12 arranged on a lead 32, and one semiconductor element 13 arranged on the lead 31. That is, the number of semiconductor elements 11 according to the present embodiments is equal to or larger than two, and they are arranged in two columns in the first direction x. In the manufacturing of the semiconductor device A30, the inflow port G is preferably provided in the vicinity of the lead 31.

The plurality of semiconductor elements 11 are aligned along the second direction y. The plurality of semiconductor elements 11 include a plurality of semiconductor elements 11A arranged in a first column and a plurality of semiconductor elements 11B arranged in a second column separated from the first column in the first direction x. The first column is closer to the lead 31 than the second column. As described in the semiconductor device A21, the second column may be closer to the lead 31 than the first column. The number of columns in which the plurality of semiconductor elements 11 are arranged may be equal to or larger than two. The plurality of semiconductor elements 11A overlap when viewed in the second direction y, and the plurality of semiconductor elements 11B overlap when viewed in the second direction y.

Each semiconductor element 11 includes a first side 11a1, a second side 11a2, a third side 11a3, and a fourth side 11a4 in plan view. The first side 11a1, the second side 11a2, the third side 11a3, and the fourth side 11a4 correspond to the ends of each main surface 11a in the first direction x and the second direction y. The first side 11a1 and the second side 11a2 are separated from each other in the second direction y. The third side 11a3 and the fourth side 11a4 are separated from each other in the first direction x. The main surface 11a is not limited to having the shape illustrated in the example, and may not include at least any one of the first side 11a1, the second side 11a2, the third side 11a3, and the fourth side 11a4.

The plurality of semiconductor elements 11A are regularly arranged between the plurality of semiconductor elements 11B. Specifically, the plurality of semiconductor elements 11A may be arranged point-symmetrically with respect to the plurality of semiconductor elements 11B. In the illustrated example, the plurality of semiconductor elements 11 are arranged in zigzag. The plurality of semiconductor elements 11A arranged in the first column are positioned in the second direction y between the plurality of semiconductor elements 11B arranged in the second column. Two adjacent semiconductor elements 11 do not face each other in the second direction y. Described with reference to FIG. 24 and FIG. 25, the plurality of semiconductor elements 11 are arranged at intervals d1 in the second direction y. Each semiconductor element 11 includes the first side 11a1 and the second side 11a2 separated from each other in the second direction y in plan view. The first side 11a1 of the semiconductor element 1B faces the second side 11a2 of the semiconductor element 11A that is positioned next thereto in the second direction y. The interval d1 corresponds to the distance between the first side 11a1 and the second side 11a2 of two adjacent semiconductor elements 11. The distance between the semiconductor element 11A and the semiconductor element 11B that are adjacent to each other in the second direction y may be irregular.

Each semiconductor element 11 includes the fourth side 11a4 at a position farthest from the lead 32. The fourth side 11a4 of the semiconductor element 11A is separated from the extension of the fourth side 11a4 of the semiconductor element 11B by an interval d2 along the first direction x. In FIG. 25, the interval d2 in the present embodiment is illustrated. The distances along the first direction x between the plurality of semiconductor elements 11A and the plurality of semiconductor elements 11B may be different from each other.

Each semiconductor element 11 includes the third side 11a3 at a position closest to the lead 32. In the illustrated example, the third side 11a3 of each semiconductor element 11A does not overlap the fourth side 11a4 of each semiconductor element 11B when viewed in the second direction y. Alternatively, the third side 11a3 of each semiconductor element 11A may overlap the fourth side 11a4 of each semiconductor element 11B when viewed in the second direction y.

In FIGS. 24 and 25, first geometrical centers of gravity Ga of the plurality of semiconductor elements 11A when viewed in the third direction z and second geometrical centers of gravity Gb of the plurality of semiconductor elements 11B when viewed in the third direction z are illustrated. In the semiconductor device A30, the first geometrical center of gravity Ga is positioned obliquely to the second geometrical center of gravity Gb in plan view. Hence, the distance between the geometrical centers of gravity of the plurality of semiconductor elements 11 is large in the semiconductor device A30 as in the semiconductor device A20. Optionally, the first geometrical centers of gravity Ga of the plurality of semiconductor elements 11A may be aligned in the first direction x. Further, the second geometrical centers of gravity Gb of the plurality of semiconductor elements 11B may be aligned in the first direction x. Further, the plurality of semiconductor elements 11 are configured to form an angle θ. The angle θ corresponds to an angle formed by line segments connecting two second geometrical centers of gravity Gb of the plurality of semiconductor elements 11B to one of the first geometrical centers of gravity Ga of the plurality of semiconductor elements 11A. Alternatively, the angle θ corresponds to an angle formed by line segments connecting two first geometrical centers of gravity Ga of the plurality of semiconductor elements 11A to one of the second geometrical centers of gravity Gb of the plurality of semiconductor elements 11B.

Next, an example of an electrical configuration of the semiconductor device A30 will be described with reference to FIG. 27. FIG. 27 schematically illustrates the plurality of semiconductor elements 11, the semiconductor element 12, the semiconductor element 13, the plurality of wires 41, and the plurality of wires 42. Further, FIG. 27 illustrates the electrical configurations of the respective semiconductor elements 11, 12, and 13 by imaginary lines (two-dot chain lines).

Each of the semiconductor element 12 and the semiconductor element 13 includes the electrical configurations the number of which is the same as the plurality of semiconductor elements 11. In the illustrated example, each of four semiconductor elements 11 includes one circuit 11C, the semiconductor element 12 includes four circuits 12C, and the semiconductor element 13 includes four circuits 13C. The four circuits 11C are electrically connected to the respective four circuits 12C via the corresponding wires 41, the corresponding wires 42, and the four circuits 13C. That is, the semiconductor device A30 may include a plurality of physically independent electrical configurations according to the number of the plurality of semiconductor elements 11. In the example depicted in the drawing, two adjacent circuits 11C are arranged at an interval d11.

The actions and effects of the semiconductor device A30 are as follows.

Similarly to the semiconductor device A10, the semiconductor device A30 is configured such that the plurality of semiconductor elements 11 are separated from each other in such a manner as to be aligned along the second direction y, and thus is advantageous in reducing the occurrence of dielectric breakdown.

The semiconductor device A30 includes the plurality of semiconductor elements 11 arranged in two columns in the first direction x. According to such a configuration, the lead 31 (specifically, the island part 311) can be downsized. Further, when the semiconductor device A30 is manufactured, the resin poured from the inflow port G easily flows around the plurality of semiconductor elements 11. In particular, in the case where the inflow port G is provided in the vicinity of the lead 31, the resin easily flows around the plurality of semiconductor elements 11 in the flow path thereof. As a result, since bubbles are less likely to remain in the vicinity of the plurality of semiconductor elements 11, voids are less likely to occur in the sealing resin 5. Thus, the semiconductor device A30 is more advantageous in reducing the occurrence of dielectric breakdown while being downsized.

The semiconductor device A30 can reduce the wire flow of the wire 44. The semiconductor element 11 closest to the inflow port G among the plurality of semiconductor elements 11 is close to the tip of one of the two side leads 33B. Hence, the distance between the pad 111 of the semiconductor element 11 and the coated part 331 of the side lead 33B becomes smaller. As a result, in the wire 44 joined to the pad 111 and the coated part 331, a component extending in the first direction x is reduced. Thus, the direction in which the wire 44 extends tends to be parallel to the flow of the resin. Accordingly, the influence of the poured resin on the wire 44 is reduced, and the possibility of the occurrence of a failure in the wire 44 can be reduced.

Each semiconductor element 11A arranged in the first column includes the fourth side 11a4 at a position farthest from the lead 32, and each semiconductor element 11B arranged in the second column includes the fourth side 11a4 at a position farthest from the lead 32. The fourth side 11a4 of each semiconductor element 11A may be separated from the fourth side 11a4 of each semiconductor element 11B by 50 μm or more along the first direction x. Such a configuration is more advantageous in reducing the occurrence of dielectric breakdown since the distance between each semiconductor element 11A and each semiconductor element 11B is secured.

Each semiconductor element 11A includes the third side 11a3 at a position closest to the lead 32. The third side 11a3 of each semiconductor element 11A need not overlap the fourth side 11a4 of each semiconductor element 11B arranged in the first column when viewed in the second direction y. This means that there is a gap between each semiconductor element 11A and each semiconductor element 11B in the first direction x. The gap allows the resin flowing from the inflow port G toward the plurality of semiconductor elements 11 to spread more smoothly in the second direction y. As a result, since bubbles are less likely to remain in the vicinity of the plurality of semiconductor elements 11, the occurrence of the voids in the sealing resin 5 is reduced. Thus, such a configuration is more advantageous in reducing the occurrence of dielectric breakdown.

The semiconductor element 11B arranged in the second column may be positioned between two semiconductor elements 11A arranged in the first column in the second direction y. That is, the first side 11a1 and the second side 11a2 need not face each other in both of two adjacent semiconductor elements 11. This makes it easier for the resin to enter between the first side 11a1 and the second side 11a2 of the two adjacent semiconductor elements 11. Therefore, such a configuration can further reduce the occurrence of the voids in the sealing resin 5.

Each semiconductor element 11A arranged in the first column may include the first geometrical center of gravity Ga when viewed in the third direction z, and each first geometrical center of gravity Ga may be aligned in the first direction x. Such a configuration makes it easier to densely arrange the plurality of semiconductor elements 11 in the second direction y, so that the dimension of the semiconductor device A30 in the second direction y can be reduced.

Further, each semiconductor element 11B arranged in the second column may include the second geometrical center of gravity Gb when viewed in the third direction z, and each second geometrical center of gravity Gb may be aligned in the first direction x. According to such a configuration, since the plurality of semiconductor elements 11 are regularly arranged in two columns in the first direction x, heat from the plurality of semiconductor elements 11 can be efficiently dispersed.

The plurality of semiconductor elements 11A may be arranged point-symmetrically with respect to the plurality of semiconductor elements 11B. Such a configuration makes it possible to reduce unbalanced arrangement of the plurality of semiconductor elements 11 on the island part 311. This is advantageous in making the lead 31 less likely to deform.

The semiconductor element 12 and the semiconductor element 13 include the plurality of circuits 12C and 13C corresponding to the number of the plurality of semiconductor elements 11, respectively. The circuits 12C of the semiconductor element 12 may be electrically connected to one circuit 11C of the plurality of semiconductor elements 11. In such a configuration, for example, an electrical signal via each lead 34 is individually transmitted from the semiconductor element 12 to one of the plurality of semiconductor elements 11 through the semiconductor element 13. This means that an electrical signal can be independently transmitted via each of the plurality of semiconductor elements 11. Compared with the case where such a circuit configuration is realized by one semiconductor element 11, since the sealing resin 5 is interposed between the plurality of semiconductor elements 11 in the semiconductor device A30, electrical signals are more reliably divided between the plurality of semiconductor elements 11. Hence, the plurality of semiconductor elements 11 can be brought close to each other. Thus, such a configuration is advantageous in downsizing while reducing dielectric breakdown.

In the case where the examples depicted in the semiconductor device A30 are included in the description of the claims, the terms may correspond to the following. The lead 31, the lead 32, and the lead 33 correspond to a “second lead,” a “first lead,” and a “third lead,” respectively. Further, the plurality of semiconductor elements 11 and the semiconductor element 12 may correspond to “a plurality of second semiconductor elements,” and “at least one first semiconductor element,” respectively. Further, the pad 111 may correspond to a “first pad.” Further, the fourth side 11a4 of the semiconductor element 11A, the fourth side 11a4 of the semiconductor element 11B, and the third side 11a3 of the semiconductor element 11A may correspond to a “first end,” a “second end,” and a “third end,” respectively. Further, the wire 44 and the wire 41 may correspond to a “first wire” and a “second wire,” respectively. In addition, the pad 132, the pad 131, and the seal ring part 133 may correspond to a “second pad,” a “third pad,” and a “seal ring part,” respectively.

### Fourth Embodiment

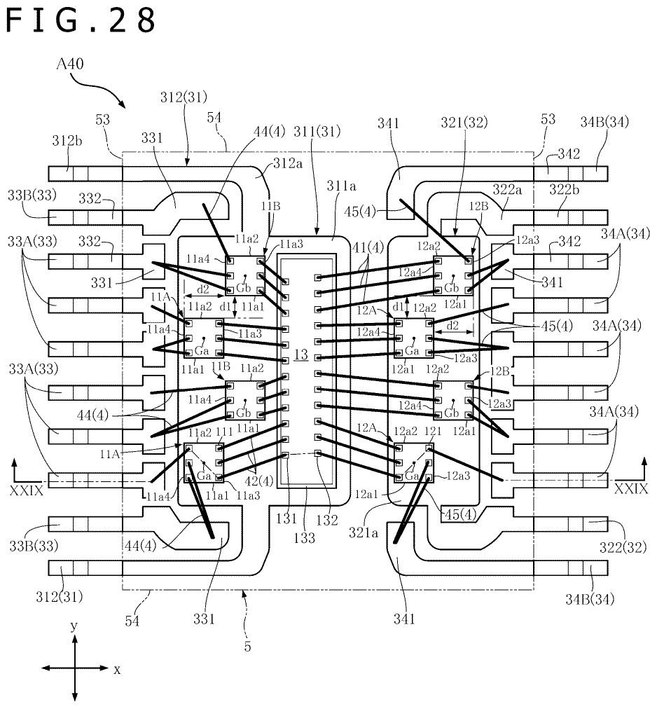

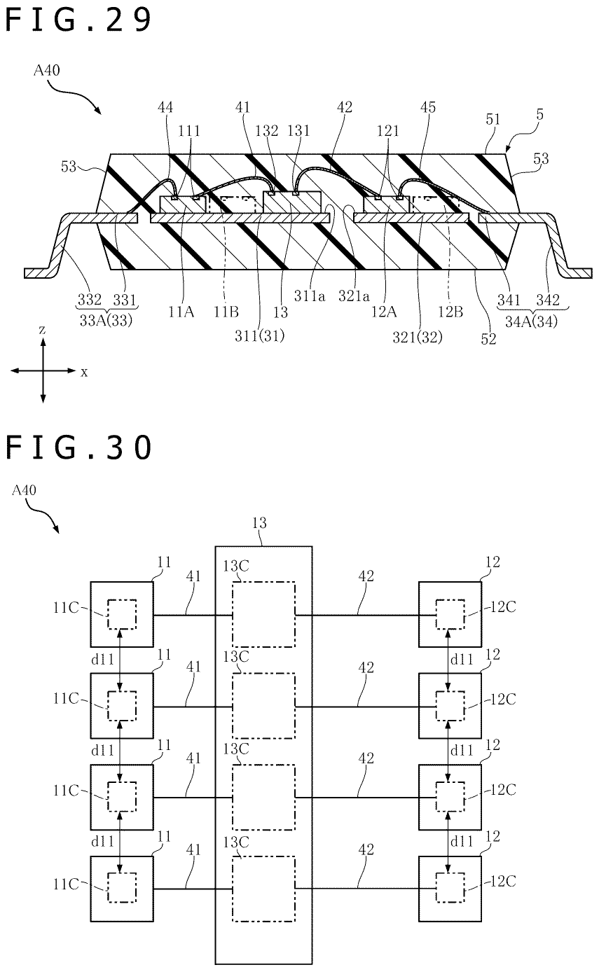

FIGS. 28 through 30 depict a semiconductor device A40 according to a fourth embodiment. The semiconductor device A40 differs from the semiconductor devices A10, A20, and A30 in the configurations of the plurality of semiconductor elements 11, 12, and 13. The semiconductor device A40 has a plurality of semiconductor elements 12 arranged in zigzag as in the semiconductor device A20 and a plurality of semiconductor elements 11 arranged in zigzag as in the semiconductor device A30. In the description of the semiconductor device A40, parts overlapping those of the semiconductor device A20 and the semiconductor device A30 are also omitted.

In the present embodiment, the plurality of semiconductor elements 11 include a plurality of semiconductor elements 11A arranged in a first column and a plurality of semiconductor elements 11B arranged in a second column separated from the first column in the first direction x. Further, the plurality of semiconductor elements 12 include a plurality of semiconductor elements 12A arranged in a third column and a plurality of semiconductor elements 12B arranged in a fourth column separated from the third column in the first direction x. The first column and the second column may be reversed, and further, the third column and the fourth column may be reversed.

The first side 11a1 and the second side 11a2 of two adjacent semiconductor elements 11 may be separated from each other at an interval d1. Further, the first side 12a1 and the second side 12a2 of two adjacent semiconductor elements 12 may be separated from each other at an interval d1. The fourth side 11a4 of the semiconductor element 11B may be separated from the extension of the fourth side 11a4 of the semiconductor element 11A by an interval d2 along the first direction x. Further, the third side 12a3 of the semiconductor element 12A may be separated from the extension of the third side 12a3 of the semiconductor element 12B by an interval d2 along the first direction x. As described above, the plurality of semiconductor elements 11 may be regularly arranged similarly to the plurality of semiconductor elements 12. More specifically, the geometrical centers of gravity of the plurality of semiconductor elements 11 and the plurality of semiconductor elements 12 may be similarly positioned. In FIG. 28, first geometrical centers of gravity Ga of the plurality of semiconductor elements 11A when viewed in the third direction z, second geometrical centers of gravity Gb of the plurality of semiconductor elements 11B when viewed in the third direction z, third geometrical centers of gravity Ga of the plurality of semiconductor elements 12A when viewed in the third direction z, and fourth geometrical centers of gravity Gb of the plurality of semiconductor elements 12B when viewed in the third direction z are illustrated. Each first geometrical center of gravity Ga may be aligned with each third geometrical center of gravity Ga in the second direction y, and each second geometrical center of gravity Gb may be aligned with each fourth geometrical center of gravity Gb in the second direction y.

Next, an example of an electrical configuration of the semiconductor device A40 will be described with reference to FIG. 30. FIG. 30 schematically illustrates the plurality of semiconductor elements 11, the plurality of semiconductor elements 12, the semiconductor element 13, the plurality of wires 41, and the plurality of wires 42. Further, FIG. 30 illustrates the electrical configurations of the respective semiconductor elements 11, 12, and 13 by imaginary lines (two-dot chain lines).

The semiconductor element 13 includes the electrical configurations the number of which is the same as the plurality of semiconductor elements 11 and the plurality of semiconductor elements 12. In the illustrated example, each of four semiconductor elements 11 includes one circuit 11C, each of four semiconductor elements 12 includes one circuit 12C, and the semiconductor element 13 includes four circuits 13C. The four circuits 11C are electrically connected to the respective four circuits 12C via the corresponding wires 41, the corresponding wires 42, and the four circuits 13C. That is, the semiconductor device A40 may include a plurality of physically independent electrical configurations according to the numbers of the plurality of semiconductor elements 11 and the plurality of semiconductor elements 12. In the example depicted in the drawing, two adjacent circuits 11C and two adjacent circuits 12C are arranged at intervals d11. Alternatively, the interval between the two adjacent circuits 11C may be different from the interval between the two adjacent circuits 12C.

The actions and effects of the semiconductor device A40 are as follows.

Similarly to the semiconductor device A10, the semiconductor device A40 is configured such that the plurality of semiconductor elements 12 are separated from each other in such a manner as to be aligned along the second direction y, and thus is advantageous in reducing the occurrence of dielectric breakdown. Further, the semiconductor device A40 can exhibit effects similar to those of the semiconductor device A20 and the semiconductor device A30 by making the configurations common thereto.

The semiconductor device A40 includes the plurality of semiconductor elements 12 arranged in zigzag and the plurality of semiconductor elements 11 arranged in zigzag. Hence, both the lead 31 (specifically, the island part 311) and the lead 32 (specifically, the island part 321) can be downsized.

In the semiconductor device A40, the plurality of semiconductor elements 11 and the plurality of semiconductor elements 12 are regularly arranged. Hence, heat can be efficiently dispersed in both the lead 31 and the lead 32. This is advantageous in causing a large current to flow through the semiconductor device A40.

In the semiconductor device A40, each first geometrical center of gravity Ga may be aligned with each third geometrical center of gravity Ga in the second direction y, and each second geometrical center of gravity Gb may be aligned with each fourth geometrical center of gravity Gb in the second direction y. According to such a configuration, the manufacturing of the semiconductor device A40 becomes more efficient. This is because the positions of the geometrical centers of gravity of the plurality of semiconductor elements 11 and 12 are aligned, and thus reference adjustment such as wire bonding is simplified.

The semiconductor element 13 includes the plurality of circuits 13C corresponding to the numbers of the plurality of semiconductor elements 11 and the plurality of semiconductor elements 12. According to such a configuration, a signal having passed through one of the plurality of semiconductor elements 11 is delivered to one of the plurality of semiconductor elements 12 via one of the plurality of circuits 13C. The sealing resin 5 is interposed between the plurality of semiconductor elements 11, and is also interposed between the plurality of semiconductor elements 12. Therefore, the semiconductor device A40 can more independently transmit a current via the lead 33. This is advantageous in further improving the dielectric breakdown voltage of the semiconductor device A40.

In the case where the examples depicted in the semiconductor device A40 are included in the description of the claims, the terms may correspond to the following. The lead 31, the lead 32, and the lead 34 correspond to a “first lead,” a “second lead,” and a “third lead,” respectively. Further, the plurality of semiconductor elements 11 and the plurality of semiconductor elements 12 may correspond to “a plurality of first semiconductor elements” and “a plurality of second semiconductor elements,” respectively. Further, the pad 121 may correspond to a “first pad.” Further, the third side 12a3 of the semiconductor element 12A, the third side 12a3 of the semiconductor element 12B, and the fourth side 12a4 of the semiconductor element 12A may correspond to a “first end,” a “second end,” and a “third end,” respectively. Further, the wire 45 and the wire 41 may correspond to a “first wire” and a “second wire,” respectively. In addition, the pad 132, the pad 131, and the seal ring part 133 may correspond to a “second pad,” a “third pad,” and a “seal ring part,” respectively.

The semiconductor device and the manufacturing method of the semiconductor device according to the claims of the present disclosure are not limited to and interpreted as the above-described embodiments. The specific configuration of each part of the semiconductor device of the present disclosure and the specific processing of each step of the manufacturing method of the semiconductor device of the present disclosure can be changed in various designs. For example, the semiconductor device and the manufacturing method of the semiconductor device of the present disclosure include embodiments related to the following supplementary notes. It should be noted that examples of each constitutional element and each step (each processing) in the following supplementary notes are depicted in parentheses using the reference numerals in the above-described embodiments (including the modified examples), but the present invention is not limited thereto.

### [Supplementary Note 1]

A semiconductor device (A10, A20, A30, A40) including:
a first lead (31, 32);
a second lead (31, 32) separated from the first lead (31, 32) in a first direction (x);
at least one first semiconductor element (11, 12) loaded on the first lead (31, 32);
a plurality of second semiconductor elements (11, 12) loaded on the second lead (31, 32);
a third semiconductor element (13) loaded on the first lead (31, 32) or the second lead (31, 32); and
a sealing resin (5) that covers the first lead (31, 32), the second lead (31, 32), the at least one first semiconductor element (11, 12), the plurality of second semiconductor elements (11, 12), and the third semiconductor element (13),
in which the third semiconductor element (13) is interposed between the at least one first semiconductor element (11, 12) and the plurality of second semiconductor elements (11, 12) such that the at least one first semiconductor element (11, 12) and the plurality of second semiconductor elements (11, 12) have different potentials, and
the plurality of second semiconductor elements (11, 12) are aligned along a second direction (y) orthogonal to the first direction (x).

### [Supplementary Note 2]

The semiconductor device (A20, A30, A40) according to supplementary note 1,
in which the plurality of second semiconductor elements (11, 12) include a second semiconductor element (11A, 12A) arranged in a first column and a second semiconductor element (11B, 12B) arranged in a second column separated from the first column in the first direction (x).

### [Supplementary Note 3]

The semiconductor device (A20, A30, A40) according to supplementary note 2,
in which the second semiconductor element (11A, 12A) arranged in the first column includes a first end (11a4, 12a3) at a position farthest from the first lead (31),
the second semiconductor element (11B, 12B) arranged in the second column includes a second end (11a4, 12a3) at a position farthest from the first lead (31), and
the first end (11a4, 12a3) is separated from the second end (11a4, 12 a3) by 50 μm or more along the first direction (x).
   [Supplementary note 4]

The semiconductor device (A20, A30, A40) according to supplementary note 3,
in which the second semiconductor element (11B, 12B) arranged in the second column includes a third end (11a3, 12a4) closest to the first lead (31), and
the first end (11a4, 12a3) does not overlap the third end (11a3, 12a4) when viewed in the second direction (y).

### [Supplementary Note 4-1]

The semiconductor device (A20, A30, A40) according to supplementary note 3,
in which the second semiconductor element (11B, 12B) arranged in the second column includes a third end (11a3, 12a4) closest to the first lead (31), and
the first end (11a4, 12a3) overlaps the third end (11a3, 12a4) when viewed in the second direction (y).

### [Supplementary Note 5]

The semiconductor device (A20, A30, A40) according to any one of supplementary notes 2 through 4,
in which the number of second semiconductor elements (11A, 12A) arranged in the first column is equal to or larger than two, and
the second semiconductor element (11B, 12B) arranged in the second column is positioned between the two or more second semiconductor elements (11A, 12A) arranged in the first column in the second direction (y).

### [Supplementary Note 5-1]

The semiconductor device (A20, A30, A40) according to any one of supplementary notes 2 through 4,
in which the plurality of second semiconductor elements (11, 12) include two second semiconductor elements (11A, 12A) arranged in the first column and one second semiconductor element (11B, 12B) arranged in the second column, and
line segments connecting geometrical centers of gravity (Ga) of the respective two second semiconductor elements (11A, 12A) when viewed in a third direction (z) orthogonal to the first direction (x) and the second direction (y) to a geometrical center of gravity (Gb) of the one second semiconductor element (11B, 12B) when viewed in the third direction (z) forms an angle of 60° or more but 120° or less.

### [Supplementary Note 6]

The semiconductor device (A20, A30, A40) according to supplementary note 5,
in which each of the two or more second semiconductor elements (11A, 12A) arranged in the first column includes a first geometrical center of gravity (Ga) when viewed in a third direction (z) orthogonal to the first direction (x) and the second direction (y), and
the first geometrical centers of gravity (Ga) overlap when viewed in the second direction (y).

### [Supplementary Note 7]

The semiconductor device (A10, A20, A30) according to any one of supplementary notes 1 through 6,
in which each of the at least one first semiconductor element (11, 12) and the third semiconductor element (13) includes a plurality of circuits (11C, 12C, 13C) corresponding to the number of the plurality of second semiconductor elements (11, 12).

### [Supplementary Note 8]

The semiconductor device (A10, A20, A30, A40) according to supplementary note 7,
in which a corresponding one of the circuits (11C, 12C) of the at least one first semiconductor element (11, 12) is electrically connected to a corresponding one of the circuits (11C, 12C) of the plurality of second semiconductor elements (11, 12).

### [Supplementary Note 9]

The semiconductor device (A40) according to any one of supplementary notes 2 through 6, in which the number of the at least one first semiconductor element (11, 12) is equal to or larger than two, and the at least one first semiconductor element (11, 12) is arranged in each of two columns in the first direction (x).

[Supplementary note 10]

The semiconductor device (A40) according to supplementary note 9,
in which the third semiconductor element (13) includes a plurality of circuits (13C) corresponding to the numbers of the at least one first semiconductor element (11, 12) and the plurality of second semiconductor elements (11, 12).

### [Supplementary Note 11]

The semiconductor device (A10, A20, A21, A40) according to any one of supplementary notes 1 through 10,
in which the third semiconductor element (13) is loaded on the first lead (31).

### [Supplementary Note 12]

The semiconductor device (A11, A30) according to any one of supplementary notes 1 through 10,
in which the third semiconductor element (13) is loaded on the second lead (32).

### [Supplementary Note 13]

The semiconductor device (A10, A20, A30, A40) according to any one of supplementary notes 1 through 12,
in which two adjacent second semiconductor elements (11, 12) in the plurality of second semiconductor elements (11, 12) are separated from each other by 150 μm or more but 1500 μm or less along the second direction (y).

### [Supplementary Note 14]

The semiconductor device (A10, A20, A30, A40) according to any one of supplementary notes 1 through 13,further including:
a plurality of third leads (33, 34) that are electrically connected to the plurality of second semiconductor elements (11, 12); and
a plurality of first wires (44, 45) that electrically connect the plurality of third leads (33, 34) and the plurality of second semiconductor elements (11, 12) to each other.

### [Supplementary Note 14-1]

The semiconductor device (A10, A20, A30, A40) according to supplementary note 14,
in which each of the plurality of second semiconductor elements (11, 12) includes a first pad (111, 121), and
the plurality of first wires (44, 45) are joined to one first pad (111, 121) of the plurality of second semiconductor elements (11, 12).

### [Supplementary Note 15]

The semiconductor device (A10, A20, A30, A40) according to any one of supplementary notes 1 through 14,
in which the third semiconductor element (13) is an insulating element for transmitting an electrical signal between the at least one first semiconductor element (11) and the plurality of second semiconductor elements (12) in an insulated state.
   [Supplementary note 16]

The semiconductor device (A10, A20, A30, A40) according to any one of supplementary notes 1 through 15,
in which the third semiconductor element (13) includes an upper winding (135a) and a lower winding (135b) that are separated from each other in the third direction (z) and a semiconductor substrate (130) having the same potential as that of the first lead (31, 32), and
the semiconductor substrate (130) is positioned between the lower winding (135b) and the first lead (31) in the third direction (z).
   [Supplementary note 17]

The semiconductor device (A10, A20, A40) according to supplementary note 16, further including:
a plurality of second wires (41) that electrically connect the third semiconductor element (13) and the plurality of second semiconductor elements (12) to each other,
in which the third semiconductor element (13) includes a main surface (13a) facing one side in the third direction (z) and a plurality of second pads (132) arranged on the main surface (13a), and
each of the plurality of second wires (41) is joined to the plurality of second pads (132).

### [Supplementary Note 18]

The semiconductor device (A10, A20, A40) according to supplementary note 17,
in which the lower winding (135b) has the same potential as that of the semiconductor substrate (130).

### [Supplementary Note 19]

The semiconductor device (A10, A20, A40) according to supplementary note 17 or 18,
in which the third semiconductor element (13) includes a third pad (131) arranged on the main surface (13a), and
a potential of the third pad (131) is different from a potential of the second pad (132).

### [Supplementary Note 20]

The semiconductor device (A10, A20, A40) according to supplementary note 19,
in which the upper winding (135a) is conductive to the second pad (132), and
the lower winding (135b) is conductive to the third pad (131).

Finally, terms in the present disclosure will be described. The following terms in the present disclosure correspond as follows, unless otherwise stated. “An object A is formed in an object B” includes “an object A is directly formed in an object B” and “an object A is formed in an object B while another object is interposed between the object A and the object B.” “An object A is arranged in an object B” includes “an object A is directly arranged in an object B” and “an object A is arranged in an object B while another object is interposed between the object A and the object B.” “A plurality of As are arranged along a direction B” means that a plurality of As may be aligned in a direction B and may deviate to any direction other than the direction B. “An object A overlaps an object B when viewed in a certain direction” includes “an object A entirely overlaps an object B” and “an object A partially overlaps an object B.” “(The material of) an object A contains a material C” includes “a case where (the material of) an object A is made of a material C” and “a case where the main component of (the material of) an object A is a material C.” “A surface A faces (one side or the other side of) a direction B” is not limited to a case where the angle of the surface A with respect to the direction B is 90°, but includes a case where the surface A is inclined with respect to the direction B. “A surface A is orthogonal to a surface B” is not limited to a case where the angle of the surface A with respect to the surface B is 90°, but includes a case where the surface A is inclined with respect to the surface B. “A rectangular shape” is not limited to a rectangle in which the angles of four corners are 90°, but may be a rectangle in which the angles of four corners are within a range of 90°±5°, or a rounded rectangle whose four corners are rounded. “A geometrical center of gravity” means the center of gravity in a shape when a particular surface of an element is viewed in one direction. “A dimension A is the same as (equal to) a dimension B” includes a difference that is generally recognized as a manufacturing error in some cases. “A and B are aligned in a direction C” means that A and B are at the same position in the direction C while an error of a degree generally recognized as a manufacturing error is included.

The present disclosure contains subject matter related to that disclosed in Japanese Priority Patent Application JP 2025-030126 filed in the Japan Patent Office on Feb. 27, 2025, the entire content of which is hereby incorporated by reference.

What is claimed is:

1. A semiconductor device comprising:
a first lead;
a second lead separated from the first lead in a first direction;
at least one first semiconductor element loaded on the first lead;
a plurality of second semiconductor elements loaded on the second lead;
a third semiconductor element loaded on the first lead or the second lead; and
a sealing resin that covers the first lead, the second lead, the at least one first semiconductor element, the plurality of second semiconductor elements, and the third semiconductor element,
wherein the third semiconductor element is interposed between the at least one first semiconductor element and the plurality of second semiconductor elements such that the at least one first semiconductor element and the plurality of second semiconductor elements have different potentials, and
the plurality of second semiconductor elements are aligned along a second direction orthogonal to the first direction.

2. The semiconductor device according to claim 1,
wherein the plurality of second semiconductor elements include a second semiconductor element arranged in a first column and a second semiconductor element arranged in a second column separated from the first column in the first direction.

3. The semiconductor device according to claim 2,
wherein the second semiconductor element arranged in the first column includes a first end at a position farthest from the first lead,
the second semiconductor element arranged in the second column includes a second end at a position farthest from the first lead, and
the first end is separated from the second end by 50 μm or more along the first direction.

4. The semiconductor device according to claim 3,
wherein the second semiconductor element arranged in the second column includes a third end closest to the first lead, and
the first end does not overlap the third end when viewed in the second direction.

5. The semiconductor device according to claim 2,
wherein the number of second semiconductor elements arranged in the first column is equal to or larger than two, and
the second semiconductor element arranged in the second column is positioned between the two or more second semiconductor elements arranged in the first column in the second direction.

6. The semiconductor device according to claim 5,
wherein each of the two or more second semiconductor elements arranged in the first column includes a first geometrical center of gravity when viewed in a third direction orthogonal to the first direction and the second direction, and
the first geometrical centers of gravity overlap when viewed in the second direction.

7. The semiconductor device according to claim 1,
wherein each of the at least one first semiconductor element and the third semiconductor element includes a plurality of circuits corresponding to the number of the plurality of second semiconductor elements.

8. The semiconductor device according to claim 7,
wherein a corresponding one of the circuits of the at least one first semiconductor element is electrically connected to a corresponding one of the circuits of the plurality of second semiconductor elements.

9. The semiconductor device according to claim 2,
wherein the number of the at least one first semiconductor element is equal to or larger than two, and the at least one first semiconductor element is arranged in each of two columns in the first direction.

10. The semiconductor device according to claim 9,
wherein the third semiconductor element includes a plurality of circuits corresponding to the numbers of the at least one first semiconductor element and the plurality of second semiconductor elements.

11. The semiconductor device according to claim 1,
wherein the third semiconductor element is loaded on the first lead.

12. The semiconductor device according to claim 1,
wherein the third semiconductor element is loaded on the second lead.

13. The semiconductor device according to claim 1,
wherein two adjacent second semiconductor elements in the plurality of second semiconductor elements are separated from each other by 150 μm or more but 1500 μm or less along the second direction.

14. The semiconductor device according to claim 1, further comprising:
a plurality of third leads that are electrically connected to the plurality of second semiconductor elements; and
a plurality of first wires that electrically connect the plurality of third leads and the plurality of second semiconductor elements to each other.

15. The semiconductor device according to claim 1,
wherein the third semiconductor element is an insulating element for transmitting an electrical signal between the at least one first semiconductor element and the plurality of second semiconductor elements in an insulated state.
